(19) United States
(12) Patent Application Publication
(10) Pub. No.: US 2026/0150557 A1
(43) Pub. Date: May 28, 2026

(54) Display Device

(71) Applicant: LG Display Co., Ltd., Seoul (KR)

(72) Inventors: Kyu-Hwang Lee, Paju-si (KR); Jungho Bang, Paju-si (KR); Dongkyu Lee, Goyang-si (KR); Munchan Kang, Goyang-si (KR)

(21) Appl. No.: 19/334,393

(22) Filed: Sep. 19, 2025

(30) Foreign Application Priority Data
Nov. 26, 2024 (KR) 10-2024-0171112

(51) Int. Cl. H10K 59/80

(52) U.S. Cl. CPC H10K 59/873; H10K 59/879

(57) ABSTRACT

According to embodiments of the present disclosure, there is provided a display device comprising a substrate including an display area and a non-display area surrounding the display area, a plurality of inorganic insulating layers which are disposed on the non-display area of the substrate and provide a plurality of interfaces at which a difference in refractive index occurs, and a dam structure including a plurality of organic insulating layers which are disposed on the plurality of inorganic insulating layers with a predetermined width on an edge of the non-display area of the substrate and provide a plurality of interfaces at which a difference in refractive index occurs, in which end portions of the plurality of inorganic insulating layers may be aligned with an end portion of the substrate.

### CROSS REFERENCE TO RELATED APPLICATION

The present application claims priority under 35 U.S.C. §119(a) to the Republic of Korea Patent Application No. 10-2024-0171112, filed on November 26, 2024, the entire contents of which are hereby expressly incorporated by reference into the present application.

### BACKGROUND

The present disclosure relates to a display device.

Display devices are applied to various electronic devices such as TVs, mobile phones, notebooks, tablets, vehicles, wearable devices, etc.

Examples of display devices include organic light-emitting diode (OLED) display devices that emit light, liquid crystal display (LCD) devices that require a separate light source, etc.

An OLED display device has a self-emissive element and thus does not require a separate light source, enabling the implementation of display devices of various designs.

Recently, OLED display devices using a flexible substrate have been used in various shapes and sizes. A laser trimming process is used to cut a display panel of an OLED display device using a flexible substrate into a desired shape and size.

### SUMMARY

Due to an alignment tolerance of various components (a stage, a laser device, etc.) of a laser trimming device that performs a laser trimming process, a laser trimming tolerance area of about 100 µm is provided on an edge of a display panel when the display panel is designed. The laser trimming tolerance area is formed only by a flexible substrate so that cutting by laser is easy. Such a laser trimming tolerance area is a limiting factor in reducing a bezel area of the display panel.

One object of the present disclosure is to provide a display device in which a bezel area of the display panel can be reduced or minimized.

Another object of the present disclosure is also to provide a display device in which a laser trimming process of the display panel can be performed at an accurate or a relatively accurate location.

In addition, still another object of the present disclosure is to provide a display device in which damage to the display panel due to a laser trimming process can be reduced, minimized or prevented.

Objects of the present disclosure are not limited to the above-described objects, and other objects that are not mentioned will be able to be clearly understood by those skilled in the art based on the following description.

According to embodiments of the present disclosure, there is provided a display device including a substrate including an display area and a non-display area surrounding the display area, a plurality of inorganic insulating layers which are disposed on the non-display area of the substrate and provide a plurality of interfaces at which a difference in refractive index occurs, and a dam structure including a plurality of organic insulating layer which are disposed on the plurality of inorganic insulating layers with a predetermined width on an edge of the non-display area of the substrate and provide a plurality of interfaces at which a difference in refractive index occurs, wherein end portions of the plurality of inorganic insulating layers may be coincident or aligned with an end portion of the substrate.

According to embodiments of the present disclosure, there is provided a display device including a substrate, a plurality of inorganic insulating layers that are disposed on an edge of the substrate and provide a plurality of interfaces at which light is reflected, and a reflective structure that includes a plurality of organic insulating layers that are disposed on the plurality of inorganic insulating layers on the edge of the substrate with a predetermined width and provide a plurality of interfaces at which light is reflected, in which end portions of the plurality of inorganic insulating layers may be coincident or aligned with an end portion of the substrate, and a lower end portion of an outer side surface of the reflective structure may be coincident or aligned with an end portion of the substrate.

According to the embodiments of the present disclosure, by placing the light reflective structures defining the trimming area of the substrate on the edge of the substrate, it is possible to eliminate the laser trimming tolerance area and reduce or minimize the bezel area of the display panel.

In addition, according to the embodiments of the present disclosure, by placing the light reflective structures defining the trimming area of the substrate on the edge of the substrate, it is possible to perform the laser trimming process of the display panel at an accurate or a relatively accurate location.

In addition, according to the embodiments of the present disclosure, by forming the reflective structures defining the trimming area of the substrate in advance on the edge of the substrate, it is possible to reduce, minimize or prevent damage to the display panel due to the laser trimming process of the display panel.

Effects of the present disclosure are not limited to the above-described effects, and other effects that are not mentioned will be able to be clearly understood by those skilled in the art based on the above detailed description.

### BRIEF DESCRIPTION OF THE DRAWINGS

FIG. 1 is a plan view of a display device according to one exemplary embodiment of the present disclosure.

FIG. 2 is a cross-sectional view of the display device along line II-II’ in FIG. 1, schematically showing one sub-pixel of the display device according to one exemplary embodiment of the present disclosure.

FIG. 3 is a cross-sectional view of the display device along line III-III’ in FIG. 1, schematically showing an edge area of the display device according to one exemplary embodiment of the present disclosure.

FIG. 4 is a schematic cross-sectional view showing an edge area of the display device according to an exemplary embodiment of the present disclosure.

FIG. 5 is a schematic cross-sectional view showing an edge area of the display device according to an exemplary embodiment of the present disclosure.

FIG. 6 is a schematic cross-sectional view showing an edge area of the display device according to an exemplary embodiment of the present disclosure.

FIG. 7 is a schematic cross-sectional view showing an edge area of the display device according to an exemplary embodiment of the present disclosure.

FIG. 8 is a schematic cross-sectional view showing an edge area of the display device according to an exemplary embodiment of the present disclosure.

FIG. 9 is a schematic cross-sectional view showing a laser trimming process of the display device according to an exemplary embodiment of the present disclosure.

FIG. 10 is a schematic cross-sectional view showing a laser trimming process of the display device according to an exemplary embodiment of the present disclosure.

FIG. 11 is a schematic cross-sectional view showing a laser trimming process of the display device according to an exemplary embodiment of the present disclosure.

FIG. 12 is a schematic cross-sectional view showing a laser trimming process of the display device according to an exemplary embodiment of the present disclosure.

### DETAILED DESCRIPTION

Advantages and features of the present disclosure and methods for achieving them will become clear by referencing embodiments described below in detail in conjunction with the accompanying drawings. However, the present disclosure is not limited to the embodiments disclosed below but will be implemented in various different forms, these embodiments are merely provided to make the disclosure of the present disclosure complete and fully inform those skilled in the art to which the present disclosure pertains of the scope of the present disclosure.

Since shapes, dimensions (e.g. sizes, lengths, widths, thicknesses, heights, areas, volumes), ratios, angles, numbers, etc. disclosed in the drawings for describing the embodiments of the present disclosure are illustrative, the present disclosure is not limited to the items shown. The same reference number denotes the same components throughout the specification. In addition, in describing the present disclosure, when it is determined that the detailed description of a related known technology may unnecessarily obscure the gist of the present disclosure, the detailed description thereof will be omitted. When “include,” “comprise,” “have,” “consist of,” or the like described herein are used, other parts may be added unless a term such as “merely,” “only,” or the like is used. When a component is expressed in a singular form, it includes a case in which the component is provided as a plurality of components unless specifically stated otherwise.

In construing a component, the component is construed as including a margin of error or tolerance even when there is no separate explicit description related to the margin of error or tolerance.

When the positional relationship is described, for example, when the positional relationship between two parts is described using “on,” “over,” “above,” “below,” “under,” “next to,” or the like, one or more other parts may be positioned between the two parts, for example, unless a term such as “immediately,” “directly,” or “closely” is used.

When the temporal relationship is described, when the temporal relationship is described using “after,” “subsequently,” “behind,” “then,” “before,” or the like, it may also include a non-consecutive case unless a term such as “immediately” or “directly” is used.

Although terms such as first and second are used to describe various components, these components are not limited by these terms. These terms are only used to distinguish one component from another component. Therefore, a first component described below may be a second component within the technical spirit of the present disclosure.

In the description of components of the present disclosure, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” “adhered,” or “attached” to another component, the certain component may be connected, coupled, joined, adhered, or attached directly to another component, but it should be understood that still another component may be interposed between components that may be connected, coupled, joined, adhered, or attached indirectly to each other unless otherwise stated specially.

When a component or a layer is described as “coming into contact with” or “overlapping” another component or layer, the component or the layer may come into direct contact with or directly overlap another component or layer, but it should be understood that still another component may be interposed between components that may come into indirect contact with and indirectly overlap each other unless otherwise stated specially.

It should be understood that “at least one” includes any combination of one or more of associated components as well as any of the one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present disclosure may act functionally.

Features of various embodiments of the present disclosure may be coupled or combined partially or entirely, various technological interworking and driving are made possible, and the embodiments may be implemented independently of each other or implemented together in an associated relationship.

Hereinafter, various embodiments of the present disclosure will be described in detail with reference to the accompanying drawings.

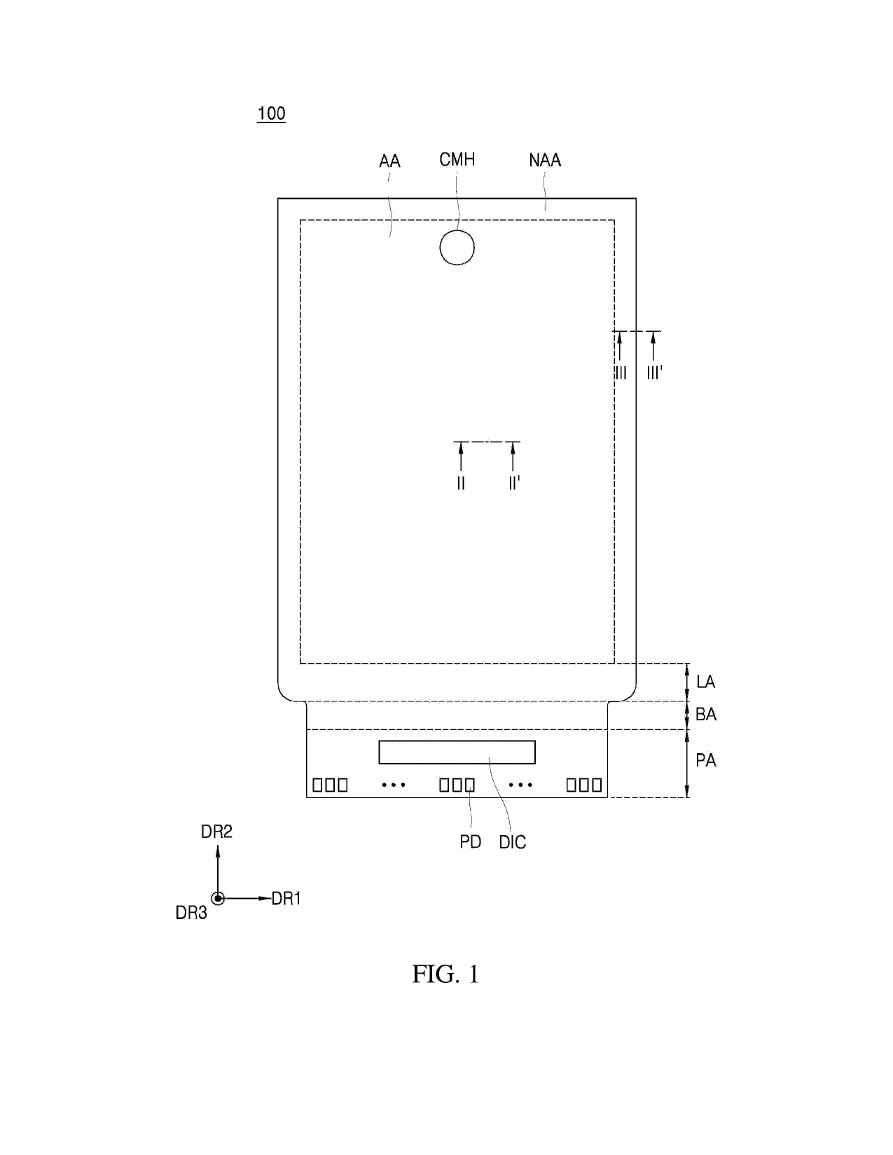

FIG. 1 is a plan view of a display device according to one exemplary embodiment of the present disclosure.

Referring to FIG. 1, a display device according to one exemplary embodiment of the present disclosure may include a display panel 100, a data driver DIC, a flexible printed circuit board, a timing controller, a power supplier, etc.

The display panel 100 may include a display area AA and a non-display area NAA. The display area AA and the non-display area NAA may be areas of a substrate and/or other layers above or below the substrate. The display area AA may be an area in which an image is implemented. The non-display area NAA may be an area in which an image is not implemented and which is positioned outside the display area AA. A camera hole CMH passing through the display panel 100 may be disposed in the display area AA. An outline of the display panel 100 and the camera hole CMH may be formed by a laser trimming process. The camera hole CMH may also be disposed in the non-display area NAA.

The display area AA may be an area in which a plurality of pixels is arranged. Each pixel may include a plurality of sub-pixels. The non-display area NAA may be an area in which a gate driver, various link lines, various power supply lines, etc. are disposed. A camera module may be disposed in the camera hole CMH of the display area AA.

The display area AA may include a plurality of data lines and a plurality of gate lines that are disposed to intersect each other. The plurality of gate lines may extend, for example, in a first direction DR1, and the plurality of data lines may extend, for example, in a second direction DR2. The data line may transmit a data signal generated by the data driver DIC to the sub-pixel, and the gate line may transmit gate signals generated by the gate driver to the sub-pixel.

The gate driver (not shown) may be disposed, for example, in the non-display area NAA positioned at left and right sides of the display area AA. The gate driver may be disposed directly on the substrate of the display panel 100 in a gate driver in panel (GIP) type.

The non-display area NAA may be disposed to surround the display area AA, and may also be referred to as “bezel area”. For example, when the display area AA may have a quadrangular shape, the non-display area NAA may be disposed at upper, lower, left, and right sides of the display area AA. The non-display area NAA positioned on the lower side of the display area AA may include a pad area PA in which the data driver DIC and a flexible printed circuit board (not shown) are bonded, a link area LA and a bending area BA that are defined between the display area AA and the pad area PA.

The data driver DIC and the flexible printed circuit board may be bonded to the pad area PA by an anisotropic conductive film. The flexible printed circuit board may be bonded to pads PD disposed on an end portion of the pad area PA. The timing controller and the power supplier may be mounted on the flexible printed circuit board.

A part of the non-display area NAA of the display panel 100 may be bent at a predetermined curvature. A bent area of the non-display area NAA of the display panel 100 may be defined as the bending area BA.

As the bending area BA of the display panel 100 is bent, the pad area PA of the non-display area NAA may be positioned to overlap the display area AA on a back surface of the display area AA. Accordingly, the lower bezel area of the display device recognized from a front surface of the display device can be reduced.

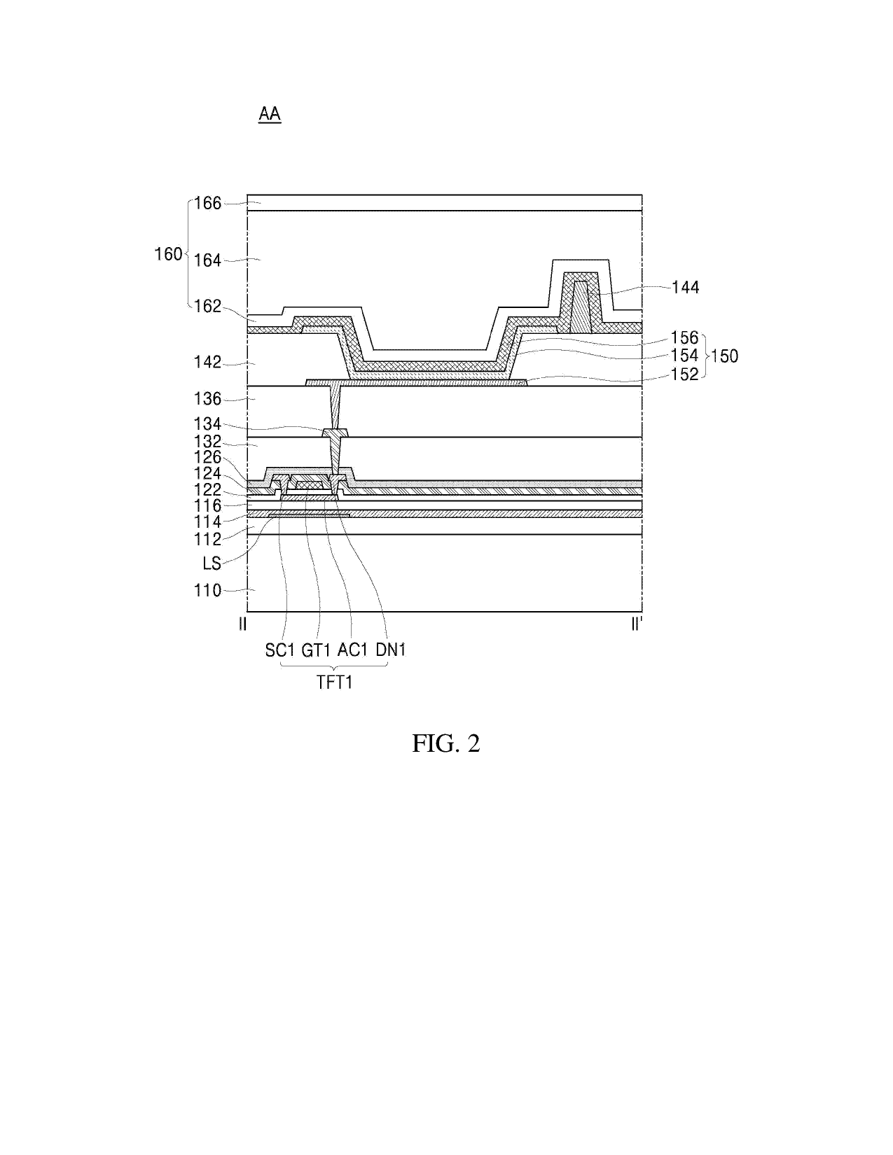

FIG. 2 is a cross-sectional view of the display device along line II-II’ in FIG. 1, schematically showing one sub-pixel of the display device according to one exemplary embodiment of the present disclosure.

Referring to FIG. 2, the display device according to one exemplary embodiment of the present disclosure may include a first thin film transistor TFT1 and a light-emitting element 150 that are disposed in the display area AA of the substrate 110, among other components.

The substrate 110 may include an insulation material. The substrate 110 may include a flexible polymer material. The substrate 110 may have a multilayered structure. For example, the substrate 110 may include a lower substrate layer and an upper substrate layer that are formed of a polymer material such as polyimide (PI), polymethylmethacrylicate (PMMA), polycarbonate (PC), polyvinyl alcohol (PVA), acrylonitrile-butadiene-styrene (ABS), polyethylene terephthalate (PET), and an intermediate layer disposed between the lower substrate layer and the upper substrate layer and formed of an inorganic insulation material.

A first buffer layer 112 may be disposed on the substrate 110. The first buffer layer 112 may completely cover the display area AA of the substrate 110. The first buffer layer 112 may include an insulation material different from that of the substrate. For example, the first buffer layer 112 may include an inorganic insulation material such as silicon oxide, silicon nitride, and silicon oxynitride.

A second buffer layer 114 may be disposed on the first buffer layer 112. For example, the second buffer layer 114 may include a different material from the first buffer layer 112. The second buffer layer 114 may include an insulation material. For example, the second buffer layer 114 may include an inorganic insulation material such as silicon oxide, silicon nitride, and silicon oxynitride.

A light-blocking layer LS may be disposed at a predetermined position between the first buffer layer 112 and the second buffer layer 114. The light-blocking layer LS may include a metal material. For example, the light-blocking layer LS may include a metal material such as aluminum (Al), chromium (Cr), copper (Cu), titanium (Ti), molybdenum (Mo), gold (Au), nickel (Ni), and tungsten (W).

A third buffer layer 116 may be disposed on the second buffer layer 114. For example, the third buffer layer 116 may include a different material from the second buffer layer 114. The third buffer layer 116 may include an insulation material. For example, the third buffer layer 116 may include an inorganic insulation material such as silicon oxide, silicon nitride, and silicon oxynitride.

A first thin film transistor TFT1 may be disposed above the light-blocking layer LS. The first thin film transistor TFT1 may be electrically connected to the light-emitting element 150. The first thin film transistor TFT1 may include a first semiconductor pattern AC1, a first gate electrode GT1, a first source electrode SC1, and a first drain electrode DN1. The first semiconductor pattern AC1 may be disposed on the third buffer layer 116.

The first semiconductor pattern AC1 may be disposed to overlap the light-blocking layer LS. Light passing through the substrate 110 and traveling toward the first semiconductor pattern AC1 may be blocked by the light-blocking layer LS. Accordingly, a change in the characteristics of the first thin film transistor TFT1 due to external light can be prevented or at least reduced. The first semiconductor pattern AC1 may include a semiconductor material. For example, the first semiconductor pattern AC1 may include a polycrystalline semiconductor (e.g., low temperature polycrystalline semiconductor (LTPS)) material or an oxide semiconductor material.

A gate insulating layer 122 may be disposed on the first semiconductor pattern AC1. The gate insulating layer 122 may extend outward from the first semiconductor pattern AC1. For example, side surfaces of the first semiconductor pattern AC1 may be covered by the gate insulating layer 122. For example, the gate insulating layer 122 may extend along an upper surface of the third buffer layer 116. The gate insulating layer 122 may include an insulation material. For example, the gate insulating layer 122 may include an inorganic insulation material such as silicon oxide, silicon nitride, and silicon oxynitride. The gate insulating layer 122 may include a material having a high dielectric constant. For example, the gate insulating layer 122 may include a high-k oxide such as hafnium oxide, or a zirconium oxide.

The first gate electrode GT1 may be disposed on the gate insulating layer 122. The first gate electrode GT1 may include a conductive material. For example, the first gate electrode GT1 may include a metal material such as aluminum (Al), chromium (Cr), copper (Cu), titanium (Ti), molybdenum (Mo), gold (Au), nickel (Ni), and tungsten (W). The first gate electrode GT1 may be electrically insulated from the first semiconductor pattern AC1 by the gate insulating layer 122. The first gate electrode GT1 may overlap a first channel area of the first semiconductor pattern AC1.

An interlayer insulating layer 124 may be disposed on the first gate electrode GT1. The interlayer insulating layer 124 may extend outward from the first gate electrode GT1. For example, side surfaces of the first gate electrode GT1 may be covered by the interlayer insulating layer 124. The interlayer insulating layer 124 may extend along an upper surface of the gate insulating layer 122. The interlayer insulating layer 124 may include a different material from the gate insulating layer 122. The interlayer insulating layer 124 may include an insulation material. For example, the interlayer insulating layer 124 may include an inorganic insulation material such as silicon oxide, silicon nitride, and silicon oxynitride.

The first source electrode SC1 and the first drain electrode DN1 may be disposed on the interlayer insulating layer 124. The first source electrode SC1 and the first drain electrode DN1 may include a conductive material. For example, the first source electrode SC1 and the first drain electrode DN1 may include a metal material such as aluminum (Al), chromium (Cr), copper (Cu), titanium (Ti), molybdenum (Mo), gold (Au), nickel (Ni), and tungsten (W). For example, the first source electrode SC1 and the first drain electrode DN1 may include a different material from the first gate electrode GT1. For example, the first source electrode SC1 and the first drain electrode DN1 may have a multilayered structure such as titanium (Ti)/aluminum (Al)/titanium (Ti).

The first source electrode SC1 and the first drain electrode DN1 may be electrically insulated from the first gate electrode GT1 by the interlayer insulating layer 124. The first source electrode SC1 may be electrically connected to a first source area of the first semiconductor pattern AC1. For example, the first source electrode SC1 may come into direct contact with the first source area of the first semiconductor pattern AC1 through a first source contact hole passing through the gate insulating layer 122 and the interlayer insulating layer 124. The first drain electrode DN1 may be electrically connected to a first drain area of the first semiconductor pattern AC1. For example, the first drain electrode DN1 may come into direct contact with the first drain area of the first semiconductor pattern AC1 through a first drain contact hole passing through the gate insulating layer 122 and the interlayer insulating layer 124.

A passivation layer 126 covering the first source electrode SC1 and the first drain electrode DN1 may be disposed on the interlayer insulating layer 124. The passivation layer 126 may include a different material from the interlayer insulating layer 124. The passivation layer 126 may include an insulation material. For example, the passivation layer 126 may include an inorganic insulation material such as silicon oxide, silicon nitride, and silicon oxynitride.

A first planarization layer 132 and a second planarization layer 136 may be sequentially stacked on the passivation layer 126. The first planarization layer 132 and the second planarization layer 136 may cover a step caused by the first thin film transistor TFT1 to provide a flat surface. For example, the first planarization layer 132 and the second planarization layer 136 may include an organic insulation material. For example, the first planarization layer 132 and the second planarization layer 136 may be formed of a photosensitive acryl-based, benzocyclobutene, polyimide-based organic material, etc. The second planarization layer 136 may include a different material from the first planarization layer 132.

An intermediate electrode 134 may be disposed on the first planarization layer 132. The light-emitting element 150 may be disposed on the second planarization layer 136. The light-emitting element 150 may include a first electrode 152, a light-emitting layer 154, and a second electrode 156. The light-emitting element 150 may be electrically connected to the first drain electrode DN1 of the first thin film transistor TFT1 through the intermediate electrode 134. For example, the intermediate electrode 134 may be connected to the first drain electrode DN1 by passing through the first planarization layer 132, and the first electrode 152 of the light-emitting element 150 may be connected to the intermediate electrode 134 by passing through the second planarization layer 136. The intermediate electrode 134 may include a conductive material. For example, the intermediate electrode 134 may include a metal material such as aluminum (Al), chromium (Cr), copper (Cu), titanium (Ti), molybdenum (Mo), gold (Au), nickel (Ni), and tungsten (W). For example, the intermediate electrode 134 may have a multilayered structure of titanium (Ti)/aluminum (Al)/titanium (Ti).

A bank layer 142 may be disposed on the second planarization layer 136. The bank layer 142 may include an organic insulation material. For example, the bank layer 142 may be formed of a photosensitive acryl-based, benzocyclobutene, polyimide-based organic material, etc. The bank layer 142 may cover an edge of the first electrode 152. The bank layer 142 may have an opening that exposes a part of the first electrode 152. The light-emitting layer 154 and the second electrode 156 of the light-emitting element 150 may be stacked on a part of the first electrode 152 exposed by the bank layer 142. A light-emitting area may be defined by the part of the first electrode 152 exposed by the opening of the bank layer 142. The first electrode 152 may include a conductive material. For example, the first electrode 152 may have high reflectivity. For example, the first electrode 152 may include a metal material such as aluminum (Al), silver (Ag) or silver-palladium-copper (APC). The first electrode 152 may have a multilayered structure. For example, the first electrode 152 may have a structure in which a metal material such as aluminum (Al) or silver (Ag) is disposed between transparent conductive materials such as ITO and IZO.

The light-emitting layer 154 may extend onto the bank layer 142. The light-emitting layer 154 may include a light-emitting material layer formed of an organic material. The light-emitting layer 154 may have a multilayered structure. For example, the light-emitting layer 154 may include a first light-emitting common layer, a light-emitting material layer, and a second light-emitting common layer. For example, the first light-emitting common layer may include at least one of a hole injection layer (HIL) and a hole transport layer (HTL). The second light-emitting common layer may include at least one of an electron transport layer (ETL) and an electron injection layer (EIL).

For example, when the sub-pixels of each pixel emit light of different colors, the light-emitting material layer of each sub-pixel may be separated from the light-emitting material layer of an adjacent sub-pixel. The light-emitting material layer of each sub-pixel may be formed separately using a fine metal mask (FMM). A spacer 144 may be disposed on the bank layer 142. The spacer 144 can prevent damage to the bank layer 142 and the light-emitting material layer formed first in an adjacent sub-pixel by the FMM. The spacer 144 may include an organic insulation material. For example, the spacer 144 may be formed of a photosensitive acryl-based, benzocyclobutene, polyimide-based organic material, etc. The spacer 144 may include a different material from the bank layer 142.

The second electrode 156 may cover the light-emitting layer 154, the bank layer 142, and the spacer 144. The second electrode 156 may be disposed in common in adjacent sub-pixels. For example, the second electrode 156 may be disposed in common in all pixels in the display area AA. The second electrode 156 may extend to the non-display area NAA outside the display area AA. The second electrode 156 may include a conductive material. For example, the second electrode 156 may be a transparent electrode formed of a transparent conductive material such as ITO and IZO.

An encapsulation part 160 may be positioned on the light-emitting element 150. The encapsulation part 160 can prevent damage to the light-emitting elements 150 due to an external impact and foreign matters such as moisture. The encapsulation part 160 may have a multilayered structure. For example, the encapsulation part 160 may include a first encapsulation layer 162, a second encapsulation layer 164, and a third encapsulation layer 166 that are sequentially stacked. For example, the first encapsulation layer 162 and the third encapsulation layer 166 may include an inorganic insulation material, and the second encapsulation layer 164 may include an organic insulation material. The encapsulation part 160 may extend to the non-display area NAA outside the display area AA.

For example, a touch sensor layer may be disposed on the encapsulation part 160.

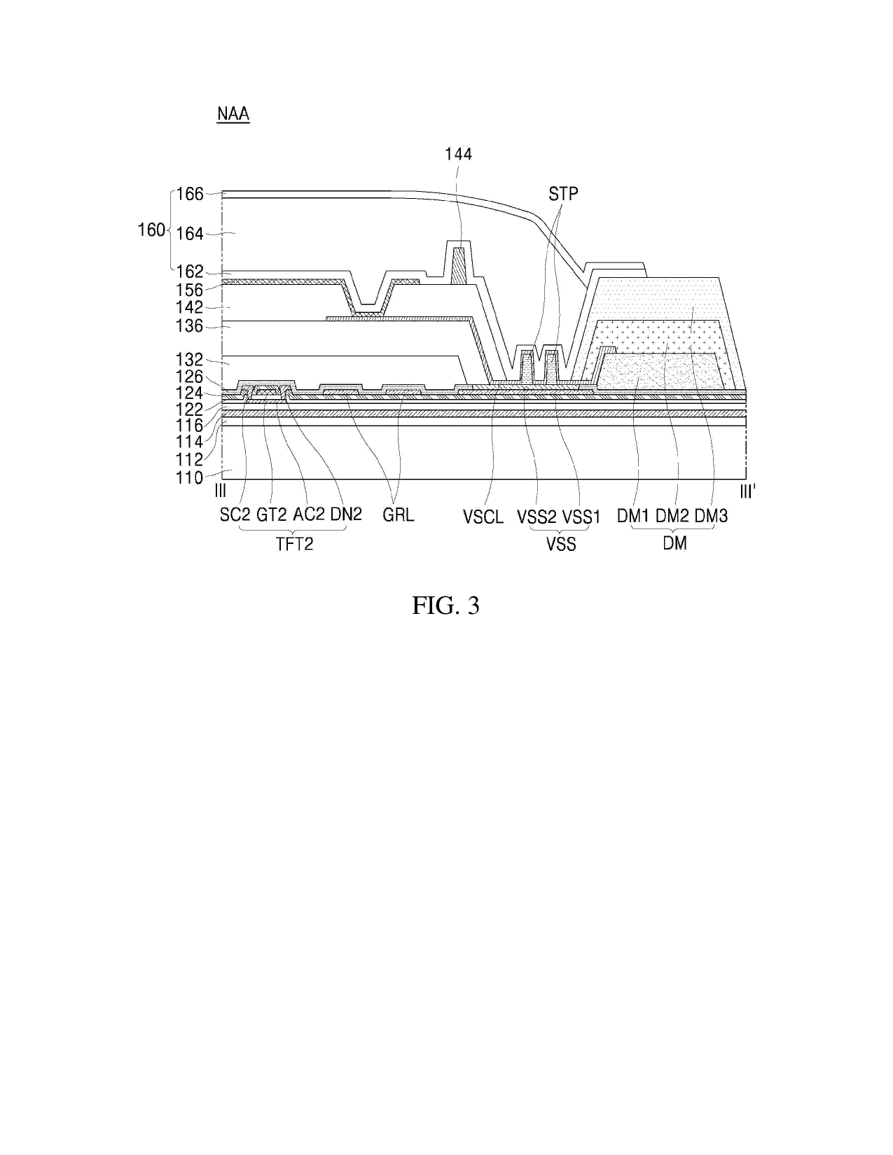

FIG. 3 is a cross-sectional view of the display device along line III-III’ in FIG. 1, schematically showing an edge area of the display device according to one exemplary embodiment of the present disclosure.

Referring to FIG. 3, the display device according to one exemplary embodiment of the present disclosure may include a second thin film transistor TFT2, a gate routing line GRL, a low-potential power line VSS, and a dam structure DM that are disposed in the non-display area NAA of the substrate 110.

The first buffer layer 112 may be disposed on the substrate 110. For example, the first buffer layer 112 may completely cover the non-display area NAA of the substrate 110. For example, an end portion of the first buffer layer 112 may be aligned (for example, coincident) with an end portion of the substrate 110.

The second buffer layer 114 may be disposed on the first buffer layer 112. For example, the second buffer layer 114 may include a different material from the first buffer layer 112. For example, the second buffer layer 114 may completely cover the non-display area NAA of the substrate 110. For example, an end portion of the second buffer layer 114 may be aligned (for example, coincident) with the end portion of the substrate 110. For example, the end portion of the second buffer layer 114 may be aligned (for example, coincident) with the end portion of the first buffer layer 112.

The third buffer layer 116 may be disposed on the second buffer layer 114. For example, the third buffer layer 116 may include a different material from the second buffer layer 114. For example, the third buffer layer 116 may completely cover the non-display area NAA of the substrate 110. For example, an end portion of the third buffer layer 116 may be aligned (for example, coincident) with the end portion of the substrate 110. For example, the end portion of the third buffer layer 116 may be aligned (for example, coincident) with the end portion of the second buffer layer 114.

The second thin film transistor TFT2 may be disposed on the third buffer layer 116. The second thin film transistor TFT2 may be a component of the gate driver. The second thin film transistor TFT2 may include a second semiconductor pattern AC2, a second gate electrode GT2, a second source electrode SC2, and a second drain electrode DN2. The second semiconductor pattern AC2 may be disposed on the third buffer layer 116.

The second semiconductor pattern AC2 may include a semiconductor material. For example, the second semiconductor pattern AC2 may include a polycrystalline semiconductor (e.g., low temperature polycrystalline semiconductor (LTPS)) material or an oxide semiconductor material.

The gate insulating layer 122 may be disposed on the second semiconductor pattern AC2. The gate insulating layer 122 may extend outward from the second semiconductor pattern AC2. For example, side surfaces of the second semiconductor pattern AC2 may be covered by the gate insulating layer 122. For example, the gate insulating layer 122 may extend along an upper surface of the third buffer layer 116. For example, the gate insulating layer 122 may completely cover the non-display area NAA of the substrate 110. For example, an end portion of the gate insulating layer 122 may be aligned (for example, coincident) with the end portion of the substrate 110. For example, the end portion of the gate insulating layer 122 may be aligned (for example, coincident) with the end portion of the third buffer layer 116.

The second gate electrode GT2 may be disposed on the gate insulating layer 122. The second gate electrode GT2 may include a conductive material. For example, the second gate electrode GT2 may include a metal material such as aluminum (Al), chromium (Cr), copper (Cu), titanium (Ti), molybdenum (Mo), gold (Au), nickel (Ni), and tungsten (W). The second gate electrode GT2 may be electrically insulated from the second semiconductor pattern AC2 by the gate insulating layer 122. The second gate electrode GT2 may overlap a second channel area of the second semiconductor pattern AC2.

The interlayer insulating layer 124 may be disposed on the second gate electrode GT2. The interlayer insulating layer 124 may extend outward from the second gate electrode GT2. For example, side surfaces of the second gate electrode GT2 may be covered by the interlayer insulating layer 124. The interlayer insulating layer 124 may extend along the upper surface of the gate insulating layer 122. The interlayer insulating layer 124 may include a different material from the gate insulating layer 122. For example, the interlayer insulating layer 124 may completely cover the non-display area NAA of the substrate 110. For example, an end portion of the interlayer insulating layer 124 may be aligned (for example, coincident) with the end portion of the substrate 110. For example, the end portion of the interlayer insulating layer 124 may be aligned (for example, coincident) with the end portion of the gate insulating layer 122. For example, the end portion of the gate insulating layer 124 may be aligned (for example, coincident) with the end portion of the third buffer layer 116.

The second source electrode SC2 and the second drain electrode DN2 may be disposed on the interlayer insulating layer 124. The second source electrode SC2 and the second drain electrode DN2 may include a conductive material. For example, the second source electrode SC2 and the second drain electrode DN2 may include a metal material such as aluminum (Al), chromium (Cr), copper (Cu), titanium (Ti), molybdenum (Mo), gold (Au), nickel (Ni), and tungsten (W). For example, the second source electrode SC2 and the second drain electrode DN2 may include a different material from the second gate electrode GT2. For example, the second source electrode SC2 and the second drain electrode DN2 may have a multilayered structure such as titanium (Ti)/aluminum (Al)/titanium (Ti).

The second source electrode SC2 and the second drain electrode DN2 may be electrically insulated from the second gate electrode GT2 by the interlayer insulating layer 124. The second source electrode SC2 may be electrically connected to a second source area of the second semiconductor pattern AC2. For example, the second source electrode SC2 may come into direct contact with the second source area of the second semiconductor pattern AC2 through a second source contact hole passing through the gate insulating layer 122 and the interlayer insulating layer 124. The second drain electrode DN2 may be electrically connected to a second drain area of the second semiconductor pattern AC2. For example, the second drain electrode DN2 may come into direct contact with the second drain area of the second semiconductor pattern AC2 through a second drain contact hole passing through the gate insulating layer 122 and the interlayer insulating layer 124. The second source electrode SC2 and the second drain electrode DN2 of the second thin film transistor TFT2 may be formed of the same material and in the same process as the first source electrode SC1 and the first drain electrode DN1 of the first thin film transistor TFT1.

The gate routing line GRL may be disposed on the interlayer insulating layer 124. The gate routing line GRL may be a line that transmits external power or signals to the gate driver. The gate routing line GRL may be disposed outside the second thin film transistor TFT2. In addition, a low-potential power line VSS may be disposed on the interlayer insulating layer 124. The low-potential power line VSS may be disposed outside the gate routing line GRL. The low-potential power line VSS may include a first low-potential power line VSS1 and a second low-potential power line VSS2. The gate routing line GRL and the first low-potential power line VSS1 may be formed of the same material and in the same process as the second source electrode SC2 and the second drain electrode DN2 of the second thin film transistor TFT2.

The passivation layer 126 covering the second source electrode SC2, the second drain electrode DN2, and the gate routing line GRL may be disposed on the interlayer insulating layer 124. The passivation layer 126 may expose a part of the first low-potential power line VSS1. The passivation layer 126 may include a different material from the interlayer insulating layer 124. For example, the passivation layer 126 may completely cover the non-display area NAA of the substrate 110. For example, an end portion of the passivation layer 126 may be aligned (for example, coincident) with the end portion of the substrate 110. For example, the end portion of the passivation layer 126 may be aligned (for example, coincident) with the end portion of the interlayer insulating layer 124.

The first buffer layer 112, the second buffer layer 114, the third buffer layer 116, the gate insulating layer 122, the interlayer insulating layer 124, and the passivation layer 126 that are disposed on the substrate 110 may provide a plurality of interfaces at which a difference in refractive index occurs. Light may be reflected at the plurality of interfaces provided by the first buffer layer 112, the second buffer layer 114, the third buffer layer 116, the gate insulating layer 122, the interlayer insulating layer 124, and the passivation layer 126. The light includes a UV laser.

The first planarization layer 132 covering the second thin film transistor TFT2 and the gate routing line GRL may be disposed on the passivation layer 126. An end portion of the first planarization layer 132 may cover an end portion of the first low-potential power line VSS1 and may be positioned on the first low-potential power line VSS1. The second planarization layer 136 may be disposed on the first planarization layer 132. The first planarization layer 132 and the second planarization layer 136 may cover a step caused by the second thin film transistor TFT2 to provide a flat surface. For example, the first planarization layer 132 and the second planarization layer 136 may include an organic insulation material. The second planarization layer 136 may include a different material from the first planarization layer 132.

The second low-potential power line VSS2 may be disposed on a part of the first low-potential power line VSS1 exposed by the passivation layer 126. The second low-potential power line VSS2 may include the same material and be formed in the same process as the intermediate electrode 134 disposed on the display area AA of the substrate 110.

The second planarization layer 136 may be disposed on the first planarization layer 132. The second planarization layer 136 may cover an upper surface and side surfaces of the first planarization layer 132. An end portion of the second planarization layer 136 may cover an end portion of the second low-potential power line VSS2 and may be positioned on the second low-potential power line VSS2.

At least one stopper STP may be disposed on the second low-potential power line VSS2. The stopper STP can restrict flow of the second encapsulation layer 164 having fluidity when the second encapsulation layer 164 is formed. The stopper STP may include the same material and be formed in the same process as the second planarization layer 136.

A low-potential power connection line VSCL may be disposed on the second planarization layer 136. The low-potential power connection line VSCL may extend outward more than the end portion of the second planarization layer 136 and cover an upper surface of the second low-potential power line VSS2 and an upper surface and side surfaces of the stopper STP. The low-potential power connection line VSCL may include the same material and be formed in the same process as the first electrode 152 of the light-emitting element 150.

The bank layer 142 may be disposed on the second planarization layer 136. The bank layer 142 may include an opening that exposes a part of the low-potential power connection line VSCL. An end portion of the bank layer 142 may be positioned between the end portion of the second planarization layer 136 and the stopper STP.

The second electrode 156 of the light-emitting element 150 may be disposed on the bank layer 142 and connected to a part of the low-potential power connection line VSCL exposed by the opening of the bank layer 142.

The spacer 144 may be disposed on the bank layer 142 adjacent to the stopper STP. The spacer 144 disposed on an edge of the bank layer 142 in the non-display area NAA can restrict flow of the second encapsulation layer 164 having fluidity when the second encapsulation layer 164 is formed.

A dam structure DM may be disposed on the passivation layer 126 with a predetermined width at the edge of the non-display area NAA of the substrate 110. The dam structure DM may be disposed continuously along the edge of the substrate 110 cut by the laser trimming process. Inner and outer side surfaces of the dam structure DM may be sloped surfaces. A width of the dam structure DM may increase toward the substrate 110. The inner side surface of the dam structure DM may be a side surface adjacent to the stopper STP, and the outer side surface thereof may be a side surface opposite to the inner side surface. The inner side surface of the dam structure DM may be a side surface facing the display area AA, and the outer side surface thereof may be a side surface opposite to the inner side surface. A lower end portion of the outer side surface of the dam structure DM may be aligned (for example, coincident) with the end portion of the substrate 110.

The dam structure DM may include a plurality of dam layers DM1, DM2, and DM3 that provide a plurality of interfaces at which a difference in refractive index occurs. Light may be reflected at the plurality of interfaces of the dam structure DM. The light includes a UV laser. The dam structure DM may be referred to as a reflective structure. For example, the dam structure DM may include a first dam layer DM1 disposed on the passivation layer 126, a second dam layer DM2 covering an upper surface and side surfaces of the first dam layer DM1, and a third dam layer DM3 covering an upper surface and side surfaces of the second dam layer DM2. For example, a lower end portion of an outer side surface of the third dam layer DM3 may be aligned (for example, coincident) with the end portion of the substrate 110. For example, the inner and outer side surfaces of the third dam layer DM3 may provide the inner and outer side surfaces of the dam structure DM. The second dam layer DM2 may include a material having a different refractive index from the first dam layer DM1. The third dam layer DM3 may include a material having a different refractive index from the second dam layer DM2. For example, the first dam layer DM1 may include the same material and be formed in the same process as the second planarization layer 136. For example, the second dam layer DM2 may include the same material and be formed in the same process as the bank layer 142. For example, the third dam layer DM3 may include the same material and be formed in the same process as the spacer 144. The dam structure DM may include the first to third dam layers DM1, DM2, and DM3, but is not limited thereto. In one embodiment, the dam structure DM may further include an additional dam layer including the same material and be formed in the same process as the first planarization layer 132 below the first dam layer DM1.

The encapsulation part 160 may be positioned on the second electrode 156. The encapsulation part 160 may have a multilayered structure. For example, the encapsulation part 160 may include a first encapsulation layer 162, a second encapsulation layer 164, and a third encapsulation layer 166 that are sequentially stacked. For example, the first encapsulation layer 162 and the third encapsulation layer 166 may include an inorganic insulation material, and the second encapsulation layer 164 may include an organic insulation material.

The first encapsulation layer 162 may cover the second electrode 156, the bank layer 142, the spacer 144, the stopper STP, the low-potential power connection line VSCL, and the inner side surface of the dam structure DM. The first encapsulation layer 162 may extend to cover a part of the upper surface of the dam structure DM. An end portion of the first encapsulation layer 162 may be positioned on the upper surface of the third dam layer DM3 of the dam structure DM.

The dam structure DM can restrict flow of the second encapsulation layer 164 having fluidity when the second encapsulation layer 164 is formed along with the stopper STP. For example, an end portion of the second encapsulation layer 164 may be positioned on the inner side surface of the dam structure DM.

The third encapsulation layer 166 may cover an upper surface of the second encapsulation layer 164. The third encapsulation layer 166 may come into contact with the first encapsulation layer 162 on the inner side surface and upper surface of the dam structure DM. An end portion of the third encapsulation layer 166 may be positioned on the upper surface of the third dam layer DM3 of the dam structure DM. The end portion of the third encapsulation layer 166 may be aligned (for example, coincident) with the end portion of the first encapsulation layer 162.

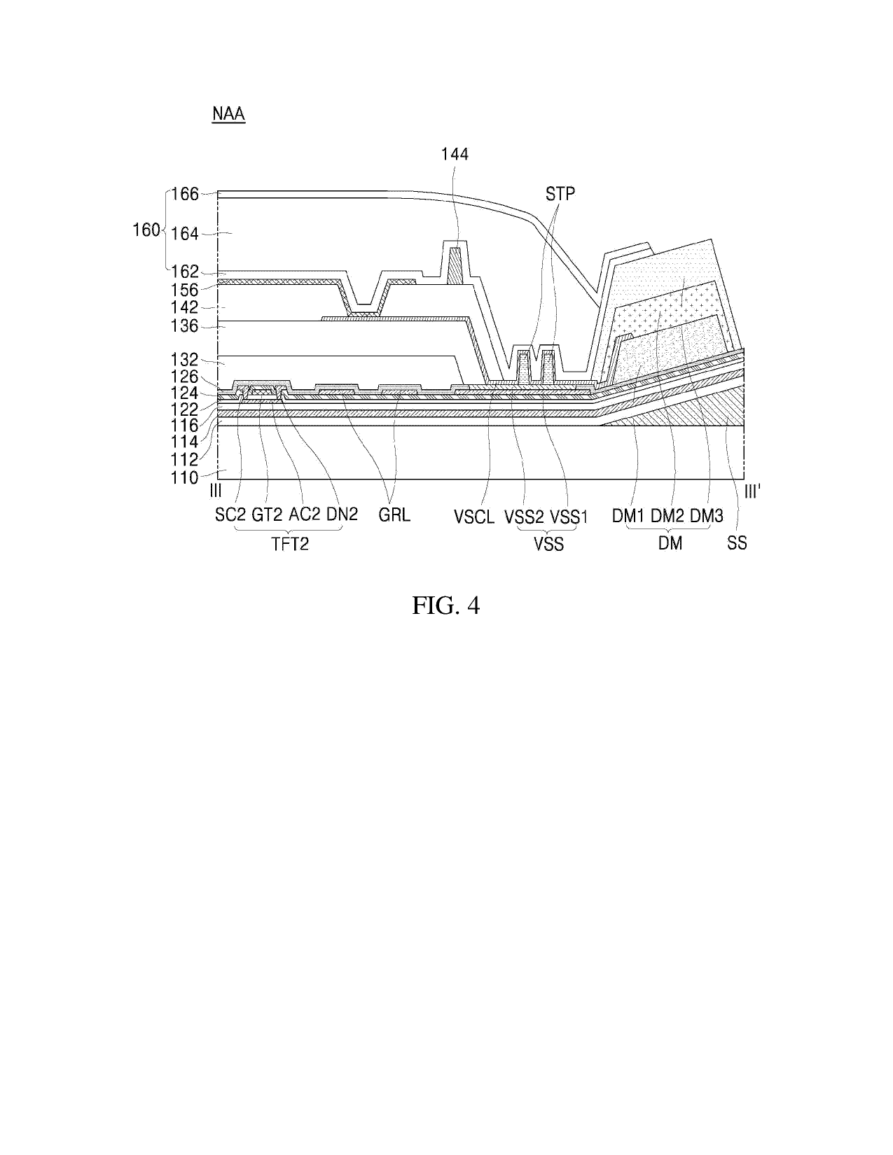

FIGS. 4 to 8 are schematic cross-sectional views showing an edge area of the display device according to embodiments of the present disclosure. Hereinafter, the display devices according to the embodiments of FIGS. 4 to 8 will be described mainly with respect to differences from the display device according to the exemplary embodiment of FIG. 3.

Referring to FIG. 4, the display device according to one exemplary embodiment of the present disclosure may further include a sloped structure SS disposed on the edge of the non-display area NAA of the substrate 110. The sloped structure SS may be disposed on the upper surface of the substrate 110. A thickness of the sloped structure SS may increase toward the end portion of the substrate 110. An end portion of the sloped structure SS may be aligned (for example, coincident) with the end portion of the substrate 110. The sloped structure SS may include an organic insulation material. For example, the sloped structure SS may include a photosensitive acryl-based, benzocyclobutene, polyimide-based organic material, etc.

On the edge of the substrate 110, the first buffer layer 112, the second buffer layer 114, the third buffer layer 116, the gate insulating layer 122, the interlayer insulating layer 124, and the passivation layer 126 may be disposed on the sloped structure SS. On the edge of the substrate 110, the first buffer layer 112, the second buffer layer 114, the third buffer layer 116, the gate insulating layer 122, the interlayer insulating layer 124, and the passivation layer 126 may be sloped with respect to the upper surface of the substrate 110 and may provide the plurality of interfaces at which a difference in refractive index occurs. The end portions of the first buffer layer 112, the second buffer layer 114, the third buffer layer 116, the gate insulating layer 122, the interlayer insulating layer 124, and the passivation layer 126 may be aligned (for example, coincident) with the end portion of the substrate 110.

The dam structure DM may be disposed on the sloped structure SS to provide the plurality of interfaces sloped with respect to the upper surface of the substrate 110. The lower end portion of the outer side surface of the dam structure DM may be aligned (for example, coincident) with the end portion of the substrate 110. For example, the lower end portion of the outer side surface of the third dam layer DM3 may be aligned (for example, coincident) with the end portion of the substrate 110.

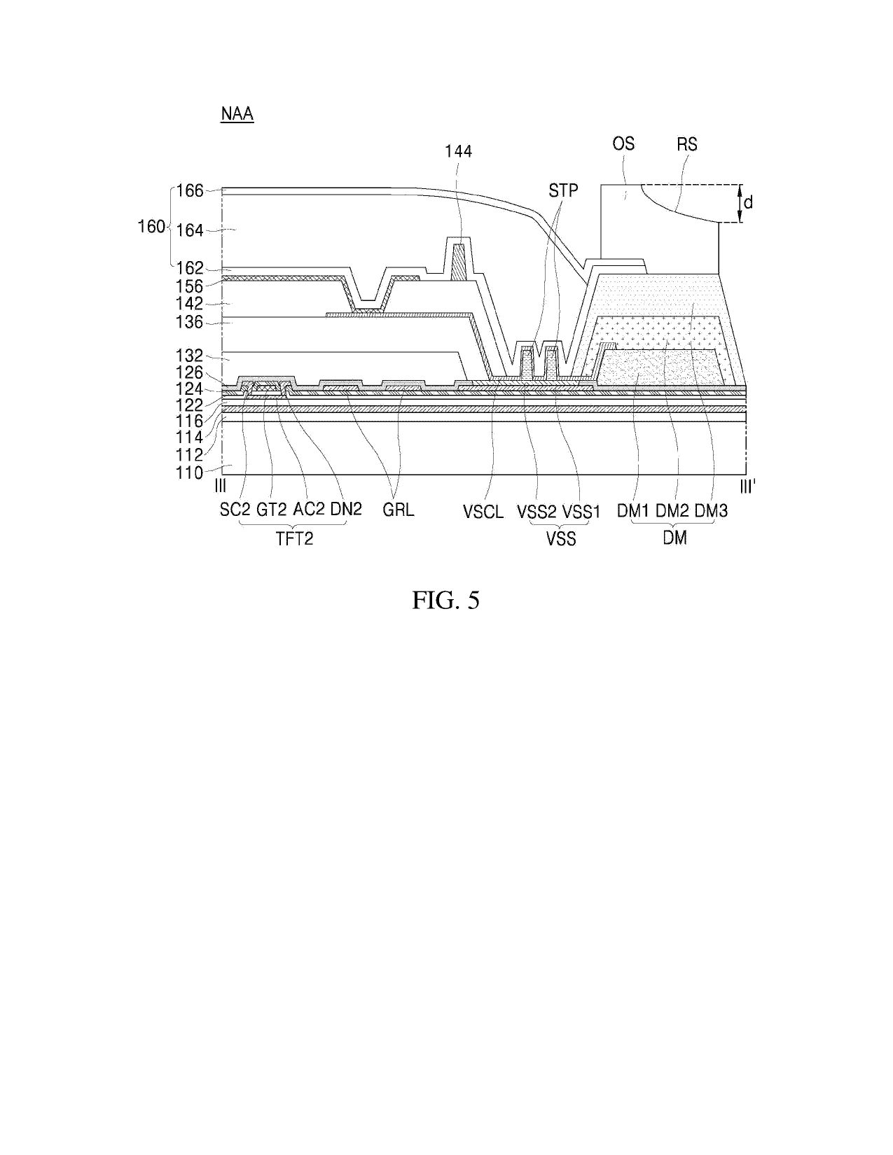

Referring to FIG. 5, the display device according to one exemplary embodiment of the present disclosure may further include an optical structure OS disposed on the edge of the non-display area NAA of the substrate 110. The optical structure OS may be disposed on the dam structure DM. The optical structure OS may include a concave curved portion RS. The concave curved portion RS may be a part of an upper surface of the optical structure OS. An edge of the concave curved portion RS of the optical structure OS may be positioned on the dam structure DM. A depth d of the concave curved portion RS may increase toward the end portion of the substrate 110. The optical structure OS may include an organic insulation material. For example, the optical structure OS may include a photosensitive acryl-based, benzocyclobutene, polyimide-based organic material, etc.

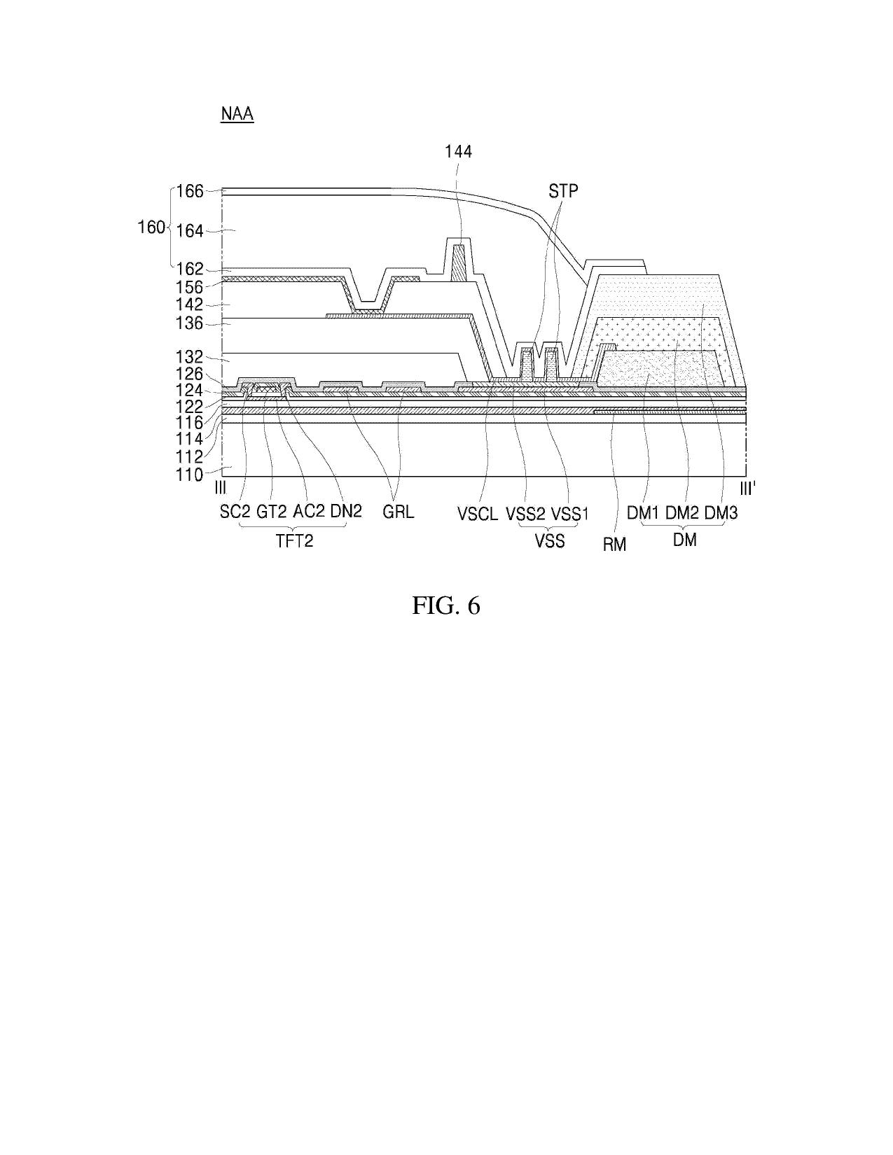

Referring to FIG. 6, the display device according to one exemplary embodiment of the present disclosure may further include a reflective layer RM overlapping the dam structure DM. The reflective layer RM may be disposed with a predetermined width below the dam structure DM. A width of the reflective layer RM may be smaller than the width of the dam structure DM. An outer end portion of the reflective layer RM may be aligned (for example, coincident) with the end portion of the substrate 110. The reflective layer RM may be disposed, for example, between the first buffer layer 112 and the second buffer layer 114. In this case, the reflective layer RM may include the same material as the light-blocking layer LS of the display area AA.

In one embodiment, the reflective layer RM may be disposed between the gate insulating layer 122 and the interlayer insulating layer 124. In this case, the reflective layer RM may include the same material and be formed in the same process as the first gate electrode GT1 of the display area AA or the same material and be formed in the same process as the second gate electrode GT2 of the non-display area NAA. In one embodiment, the reflective layer RM may be disposed between the interlayer insulating layer 124 and the passivation layer 126. In this case, the reflective layer RM may include the same material and be formed in the same process as the first source electrode SC1 or the first drain electrode DN1 of the display area AA or the same material and be formed in the same process as the second source electrode SC2 or the second drain electrode DN2 of the non-display area NAA.

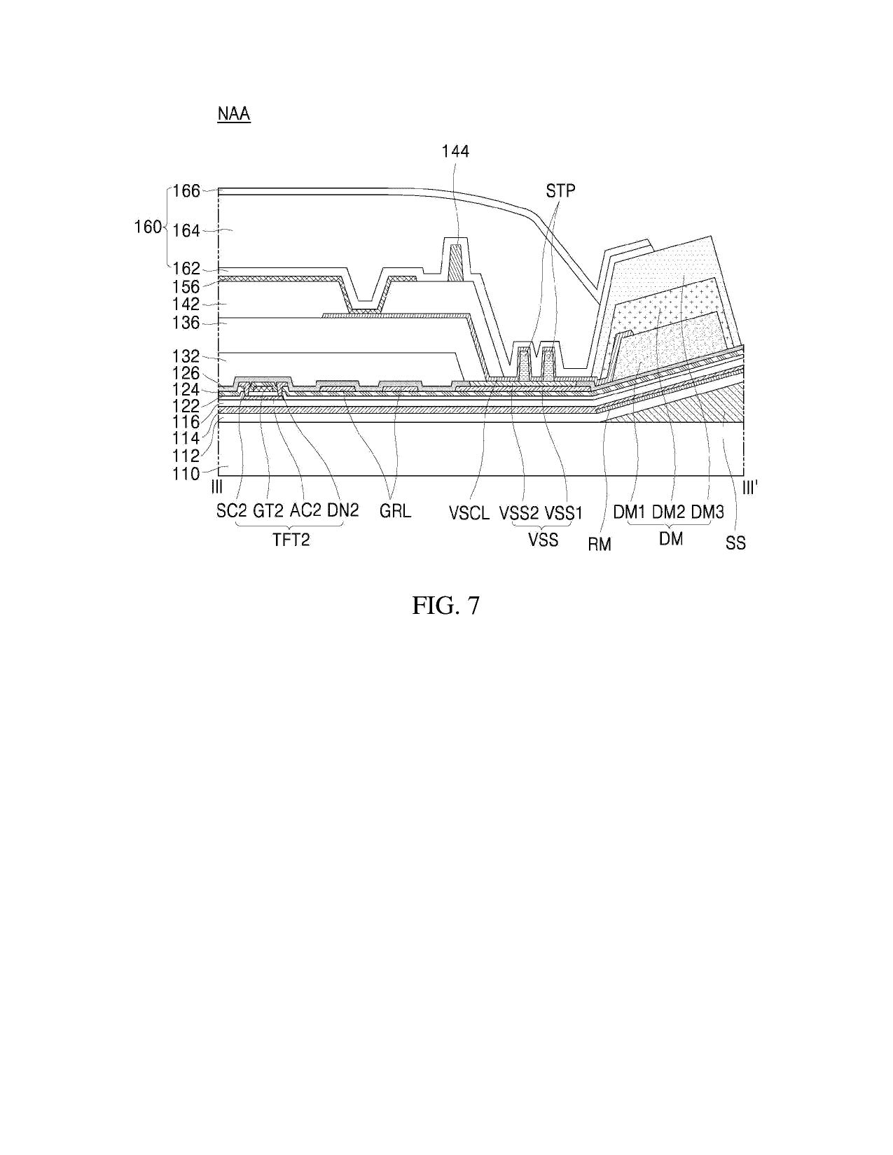

Referring to FIG. 7, the display device according to one exemplary embodiment of the present disclosure may further include the sloped structure SS disposed on the edge of the non-display area NAA of the substrate 110, and the dam structure DM, the reflective layer RM overlapping the sloped structure SS. The reflective layer RM may be disposed between the dam structure DM and the sloped structure SS.

The sloped structure SS may be disposed on the upper surface of the substrate 110. The thickness of the sloped structure SS may increase toward the end portion of the substrate 110. The end portion of the sloped structure SS may be aligned (for example, coincident) with the end portion of the substrate 110. The sloped structure SS may include an organic insulation material. For example, the sloped structure SS may include a photosensitive acryl-based, benzocyclobutene, polyimide-based organic material.

At the edge of the substrate 110, the first buffer layer 112, the second buffer layer 114, the third buffer layer 116, the gate insulating layer 122, the interlayer insulating layer 124, and the passivation layer 126 may be disposed on the sloped structure SS. On the edge of the substrate 110, the first buffer layer 112, the second buffer layer 114, the third buffer layer 116, the gate insulating layer 122, the interlayer insulating layer 124, and the passivation layer 126 may be sloped with respect to the upper surface of the substrate 110 and may provide the plurality of interfaces at which a difference in refractive index occurs. The end portions of the first buffer layer 112, the second buffer layer 114, the third buffer layer 116, the gate insulating layer 122, the interlayer insulating layer 124, and the passivation layer 126 may be aligned (for example, coincident) with the end portion of the substrate 110.

The dam structure DM may be disposed on the sloped structure SS to provide the plurality of interfaces which are sloped with respect to the upper surface of the substrate 110 and at which the difference in refractive index occurs. For example, the first dam layer DM1, the second dam layer DM2, and the third dam layer DM3 that are included in the dam structure DM may be sloped with respect to the upper surface of the substrate 110 and may provide two interfaces having a difference in refractive index. The lower end portion of the outer side surface of the dam structure DM may be aligned (for example, coincident) with the end portion of the substrate 110. For example, the lower end portion of the outer side surface of the third dam layer DM3 may be aligned (for example, coincident) with the end portion of the substrate 110.

The reflective layer RM may be disposed with a predetermined width below the dam structure DM. The width of the reflective layer RM may be smaller than the width of the dam structure DM. The outer end portion of the reflective layer RM may be aligned (for example, coincident) with the end portion of the substrate 110. The reflective layer RM may be disposed, for example, between the first buffer layer 112 and the second buffer layer 114. In this case, the reflective layer RM may include the same material and be formed in the same process as the light-blocking layer LS of the display area AA.

In one embodiment, the reflective layer RM may be disposed between the gate insulating layer 122 and the interlayer insulating layer 124. In this case, the reflective layer RM may include the same material and be formed in the same process as the first gate electrode GT1 of the display area AA or the same material and be formed in the same process as the second gate electrode GT2 of the non-display area NAA. In one embodiment, the reflective layer RM may be disposed between the interlayer insulating layer 124 and the passivation layer 126. In this case, the reflective layer RM may include the same material and be formed in the same process as the first source electrode SC1 or the first drain electrode DN1 of the display area AA or the same material and be formed in the same process as the second source electrode SC2 or the second drain electrode DN2 of the non-display area NAA.

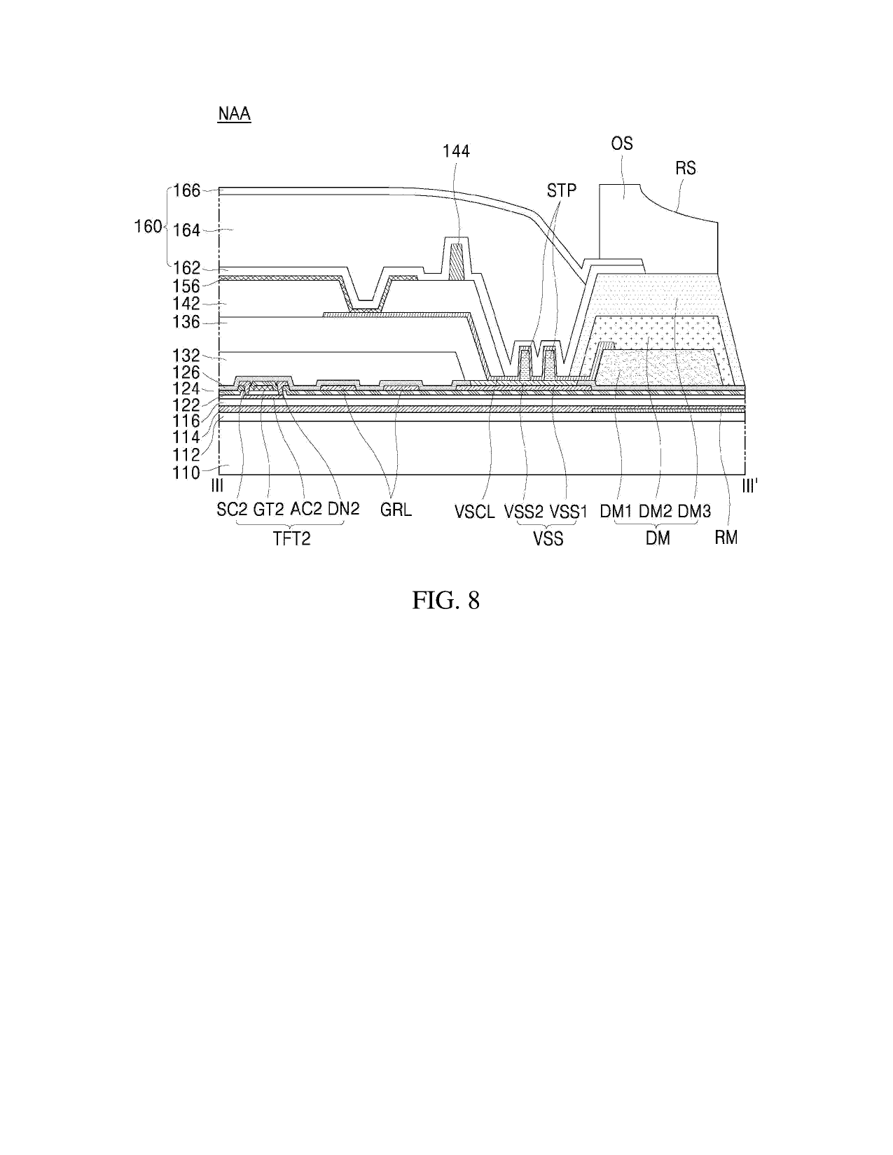

Referring to FIG. 8, the display device according to one exemplary embodiment of the present disclosure may further include the optical structure OS disposed on the edge of the non-display area NAA of the substrate 110, the dam structure DM, and the reflective layer RM overlapping the optical structure OS. The optical structure OS may be disposed on the dam structure DM.

The optical structure OS may include the concave curved portion RS. The concave curved portion RS may be a part of the upper surface of the optical structure OS. The edge of the concave curved portion RS of the optical structure OS may be positioned on the dam structure DM. The depth of the concave curved portion RS may increase toward the end portion of the substrate 110. The optical structure OS may include an organic insulation material. For example, the optical structure OS may include a photosensitive acryl-based, benzocyclobutene, polyimide-based organic material, etc.

The reflective layer RM may be disposed with a predetermined width below the dam structure DM. The width of the reflective layer RM may be smaller than the width of the dam structure DM. The outer end portion of the reflective layer RM may be aligned (for example, coincident) with the end portion of the substrate 110. The reflective layer RM may be disposed, for example, between the first buffer layer 112 and the second buffer layer 114. In this case, the reflective layer RM may include the same material and be formed in the same process as the light-blocking layer LS of the display area AA.

In one embodiment, the reflective layer RM may be disposed between the gate insulating layer 122 and the interlayer insulating layer 124. In this case, the reflective layer RM may include the same material and be formed in the same process as the first gate electrode GT1 of the display area AA or the same material and be formed in the same process as the second gate electrode GT2 of the non-display area NAA. In one embodiment, the reflective layer RM may be disposed between the interlayer insulating layer 124 and the passivation layer 126. In this case, the reflective layer RM may include the same material and be formed in the same process as the first source electrode SC1 or the second drain electrode DN2 of the display area AA or the same material and be formed in the same process as the second source electrode SC2 or the second drain electrode DN2 of the non-display area NAA.

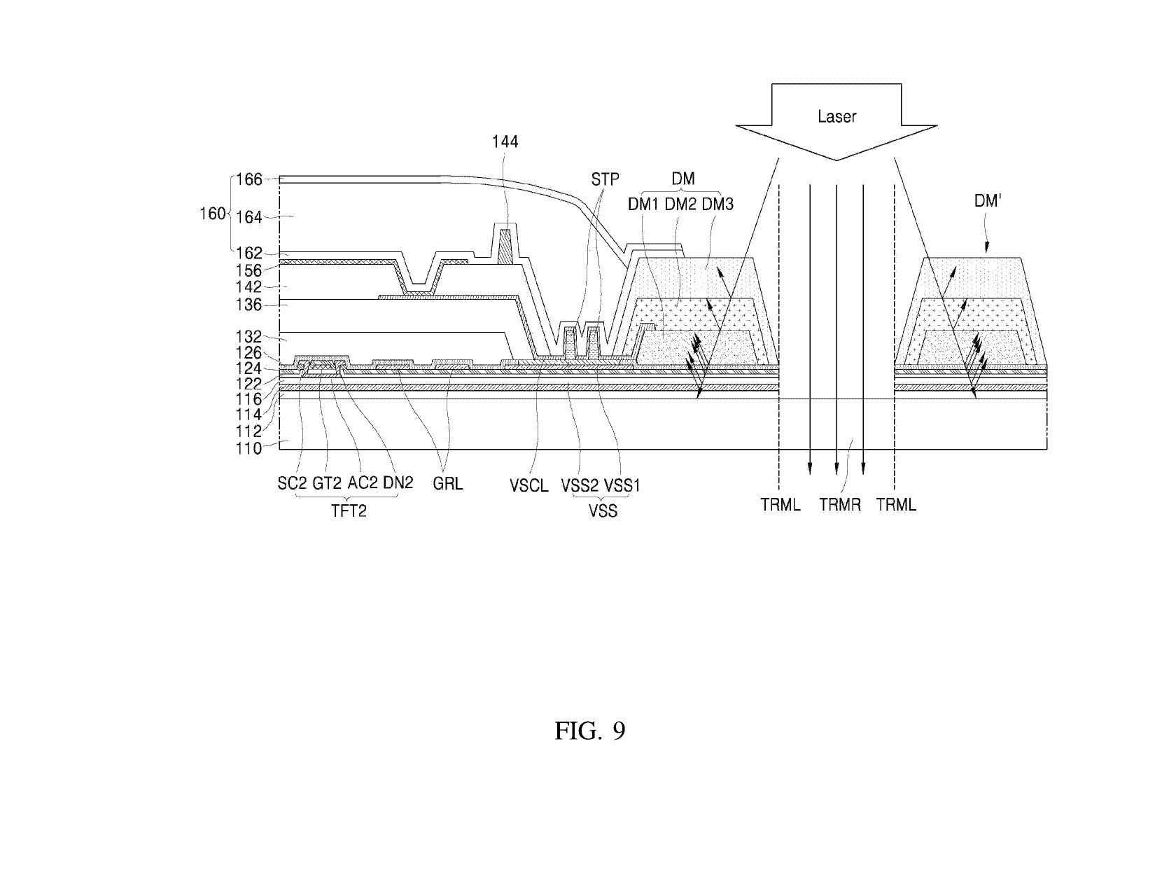

FIGS. 9 to 12 are schematic cross-sectional views showing a laser trimming process of the display device according to the embodiments of the present disclosure. The display panel 100 of the display device according to the embodiments of the present disclosure may be cut into a desired shape and size by the laser trimming process. A trimming area TRMR to be removed by the laser trimming process may be defined in advance on the edge of the substrate 110 of the display panel 100. The trimming area TRMR may be a part of the substrate 110 positioned between two trimming lines TRML.

Referring to FIG. 9, the first buffer layer 112, the second buffer layer 114, the third buffer layer 116, the gate insulating layer 122, the interlayer insulating layer 124, and the passivation layer 126 that are stacked on the edge of the non-display area NAA of the substrate 110 may include an opening that exposes the trimming area TRMR of the substrate 110. Both side surfaces of the opening passing through the first buffer layer 112, the second buffer layer 114, the third buffer layer 116, the gate insulating layer 122, the interlayer insulating layer 124, and the passivation layer 126 may provide two trimming lines TRML.

The dam structure DM and a sacrificial dam structure DM’ may be disposed at both sides of the trimming area TRMR of the substrate 110. The dam structure DM and the sacrificial dam structure DM’ may be disposed on the passivation layer 126 while exposing the trimming area TRMR of the substrate 110. The sacrificial dam structure DM’ may have the same stacked structure as the dam structure DM. The lower end portion of the outer side surface of the dam structure DM may be aligned (for example, coincident) with one sidewall of the opening of the passivation layer 126. A lower end portion of an inner side surface of a sacrificial dam structure DM’ may be aligned (for example, coincident) with the other sidewall of the opening of the passivation layer 126.

During the laser trimming process, by repeatedly radiating the laser along the edge of the substrate 110, the trimming area TRMR of the substrate 110 may be removed. The laser may be an ultrashort pulse laser having a pulse duration within a femtosecond range.

Although the laser may be radiated to a wider area than the trimming area TRMR of the substrate 110, the laser radiated to areas other than the trimming area TRMR of the substrate 110 may be reflected at the plurality of interfaces within the dam structure DM and the sacrificial dam structure DM’. In addition, the laser that has transmitted the dam structure DM and the sacrificial dam structure DM’ may be reflected at the plurality of interfaces formed by the first buffer layer 112, the second buffer layer 114, the third buffer layer 116, the gate insulating layer 122, the interlayer insulating layer 124, and the passivation layer 126. Accordingly, the trimming area TRMR of the substrate 110 may be accurately or relatively accurately removed, and areas of the substrate 110 other than the trimming area TRMR of the substrate 110 may not be removed by the laser trimming process.

Even when the laser is misaligned and radiated to the edge area of the substrate 110 due to various factors of laser trimming equipment, as described above, since the laser radiated to the areas other than the trimming area TRMR of the substrate 110 may be reflected by the stacked structure around the trimming area TRMR of the substrate 110, only the trimming area TRMR of the substrate 110 can be accurately or relatively accurately removed.

Accordingly, since there is no need to provide a laser trimming tolerance area on the edge of the substrate 110 in consideration of the misalignment of the laser trimming process, the width of the non-display area NAA of the display panel 100, that is, the bezel area, may be formed narrowly.

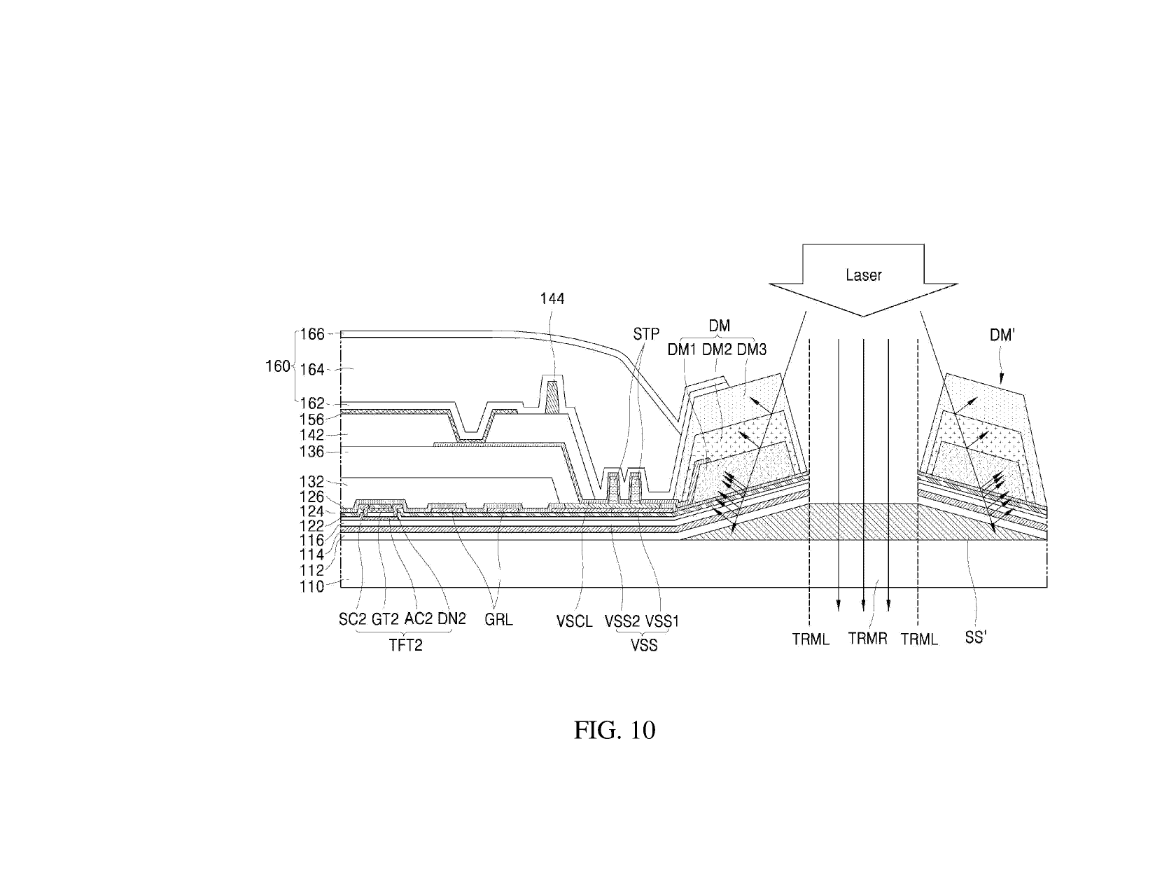

Referring to FIG. 10, a spare sloped structure SS’ may be disposed on the edge of the substrate 110. The spare sloped structure SS’ may include an inner side sloped portion, a flat portion, and an outer side sloped portion.

The first buffer layer 112, the second buffer layer 114, the third buffer layer 116, the gate insulating layer 122, the interlayer insulating layer 124, and the passivation layer 126 that are stacked on the spare sloped structure SS’ on the edge of the non-display area NAA of the substrate 110 may include an opening that exposes a flat portion of the spare sloped structure SS’. The opening passing through the first buffer layer 112, the second buffer layer 114, the third buffer layer 116, the gate insulating layer 122, the interlayer insulating layer 124, and the passivation layer 126 may provide the trimming area TRMR of the substrate 110. Both side surfaces of the opening passing through the first buffer layer 112, the second buffer layer 114, the third buffer layer 116, the gate insulating layer 122, the interlayer insulating layer 124, and the passivation layer 126 may provide two trimming lines TRML.

The dam structure DM and the sacrificial dam structure DM’ may be disposed on inner side and outer side slopes of the spare sloped structure SS’ at both sides of the trimming area TRMR of the substrate 110. The dam structure DM and the sacrificial dam structure DM’ may be disposed on the passivation layer 126 while exposing a flat portion of the spare sloped structure SS’. The sacrificial dam structure DM’ may have the same stacked structure as the dam structure DM. The lower end portion of the outer side surface of the dam structure DM may be aligned (for example, coincident) with one sidewall of the opening of the passivation layer 126. The lower end portion of the inner side surface of the sacrificial dam structure DM’ may be aligned (for example, coincident) with the other sidewall of the opening of the passivation layer 126.

Although the laser may be radiated to the wider area than the trimming area TRMR of the substrate 110, the laser radiated to areas other than the trimming area TRMR of the substrate 110 may be reflected at the plurality of interfaces within the dam structure DM and the sacrificial dam structure DM’. Since the plurality of interfaces within the dam structure DM and the sacrificial dam structure DM’ are sloped with respect to the upper surface of the substrate 110 and the laser is incident obliquely with respect to the plurality of interfaces, reflectivity with respect to the laser at the plurality of interfaces can be further improved. In addition, the laser that has transmitted the dam structure DM and the sacrificial dam structure DM’ may be reflected at the plurality of interfaces formed by the first buffer layer 112, the second buffer layer 114, the third buffer layer 116, the gate insulating layer 122, the interlayer insulating layer 124, and the passivation layer 126. Likewise, since the plurality of interfaces formed by the first buffer layer 112, the second buffer layer 114, the third buffer layer 116, the gate insulating layer 122, the interlayer insulating layer 124, and the passivation layer 126 are sloped with respect to the upper surface of the substrate 110 and the laser is incident obliquely with respect to the plurality of interfaces, the reflectivity with respect to the laser at the plurality of interfaces can be further improved. Accordingly, the flat portion of the spare sloped structure SS’ and the trimming area TRMR of the substrate 110 are accurately removed, and the areas of the substrate 110 other than the trimming area TRMR of the substrate 110 may not be removed by the laser trimming process.

Even when the laser is misaligned and radiated to the edge area of the substrate 110 due to various factors of laser trimming equipment, as described above, since the laser radiated to the areas other than the trimming area TRMR of the substrate 110 may be reflected by the stacked structure around the trimming area TRMR of the substrate 110, only the trimming area TRMR of the substrate 110 can be accurately or relatively accurately removed.

Accordingly, since there is no need to provide a laser trimming tolerance area on the edge of the substrate 110 in consideration of the misalignment of the laser trimming process, the width of the non-display area NAA of the display panel 100, that is, the bezel area, may be formed narrowly.

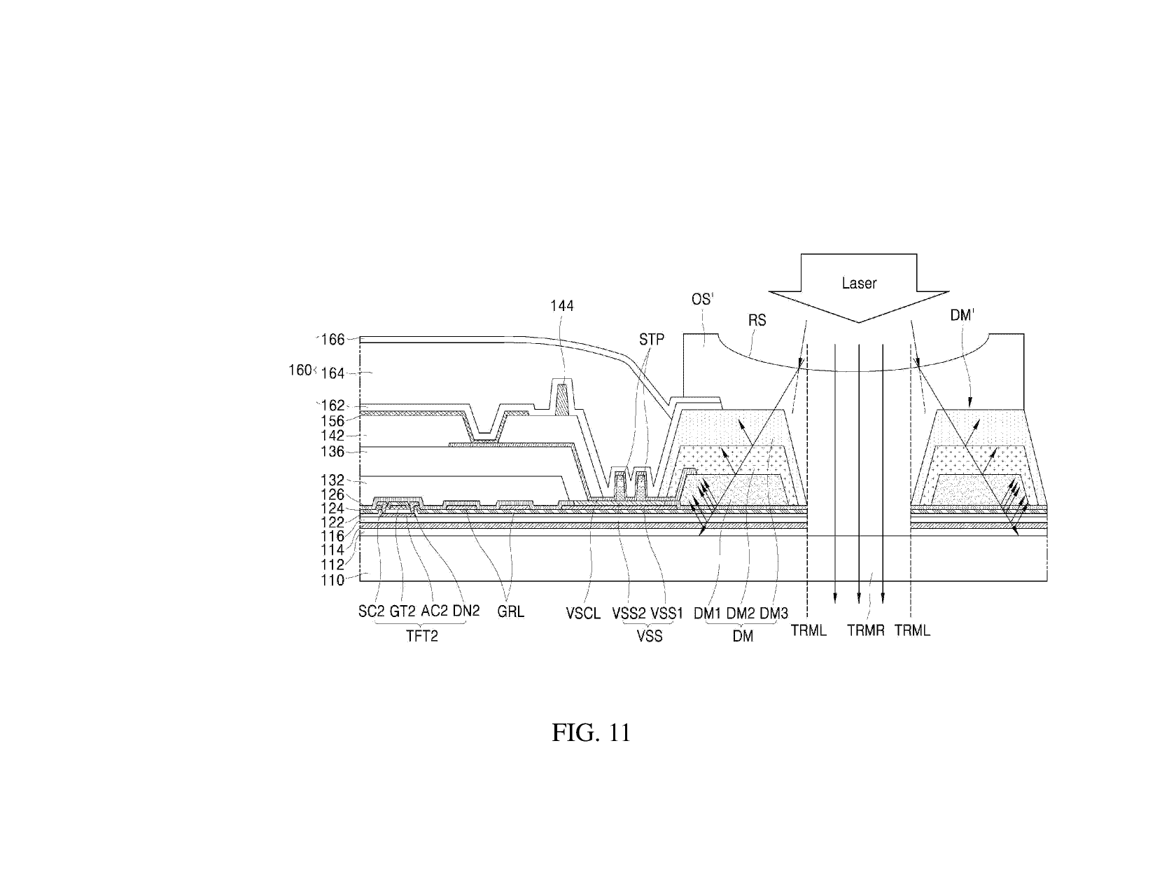

Referring to FIG. 11, the first buffer layer 112, the second buffer layer 114, the third buffer layer 116, the gate insulating layer 122, the interlayer insulating layer 124, and the passivation layer 126 that are stacked on the edge of the non-display area NAA of the substrate 110 may include an opening that exposes the trimming area TRMR of the substrate 110. Both side surfaces of the opening passing through the first buffer layer 112, the second buffer layer 114, the third buffer layer 116, the gate insulating layer 122, the interlayer insulating layer 124, and the passivation layer 126 may provide two trimming lines TRML.

The dam structure DM and a sacrificial dam structure DM’ may be disposed at both sides of the trimming area TRMR of the substrate 110. The dam structure DM and the sacrificial dam structure DM’ may be disposed on the passivation layer 126 while exposing the trimming area TRMR of the substrate 110. The sacrificial dam structure DM’ may have the same stacked structure as the dam structure DM. The lower end portion of the outer side surface of the dam structure DM may be aligned (for example, coincident) with one sidewall of the opening of the passivation layer 126. The lower end portion of the inner side surface of the sacrificial dam structure DM’ may be aligned (for example, coincident) with the other sidewall of the opening of the passivation layer 126.

In addition, the spare optical structure OS’ may be disposed on the dam structure DM and the sacrificial dam structure DM’. The spare optical structure OS’ may include the concave curved portion RS that serves as a concave lens.

Although the laser may be radiated to the wider area than the trimming area TRMR of the substrate 110, the laser radiated to areas other than the trimming area TRMR of the substrate 110 may be reflected at the plurality of interfaces within the dam structure DM and the sacrificial dam structure DM’. Since the laser is diffracted by the concave curved portion RS of the spare optical structure OS’ and is incident obliquely with respect to the plurality of interfaces within the dam structure DM and the sacrificial dam structure DM’, the reflectivity of the laser can be improved at the plurality of interfaces.

In addition, the laser that has transmitted the dam structure DM and the sacrificial dam structure DM’ may be reflected at the plurality of interfaces formed by the first buffer layer 112, the second buffer layer 114, the third buffer layer 116, the gate insulating layer 122, the interlayer insulating layer 124, and the passivation layer 126. Since the laser is incident obliquely with respect to the plurality of interfaces formed by the first buffer layer 112, the second buffer layer 114, the third buffer layer 116, the gate insulating layer 122, the interlayer insulating layer 124, and the passivation layer 126, the reflectivity with respect to the laser at the plurality of interfaces can be improved. Accordingly, the trimming area TRMR of the substrate 110 may be accurately or relatively accurately removed, and areas of the substrate 110 other than the trimming area TRMR of the substrate 110 may not be removed by the laser trimming process.

Even when the laser is misaligned and radiated to the edge area of the substrate 110 due to various factors of laser trimming equipment, as described above, since the laser radiated to the areas other than the trimming area TRMR of the substrate 110 may be reflected by the stacked structure around the trimming area TRMR of the substrate 110, only the trimming area TRMR of the substrate 110 can be accurately or relatively accurately removed.

Accordingly, since there is no need to provide a laser trimming tolerance area on the edge of the substrate 110 in consideration of the misalignment of the laser trimming process, the width of the non-display area NAA of the display panel 100, that is, the bezel area, may be formed narrowly.

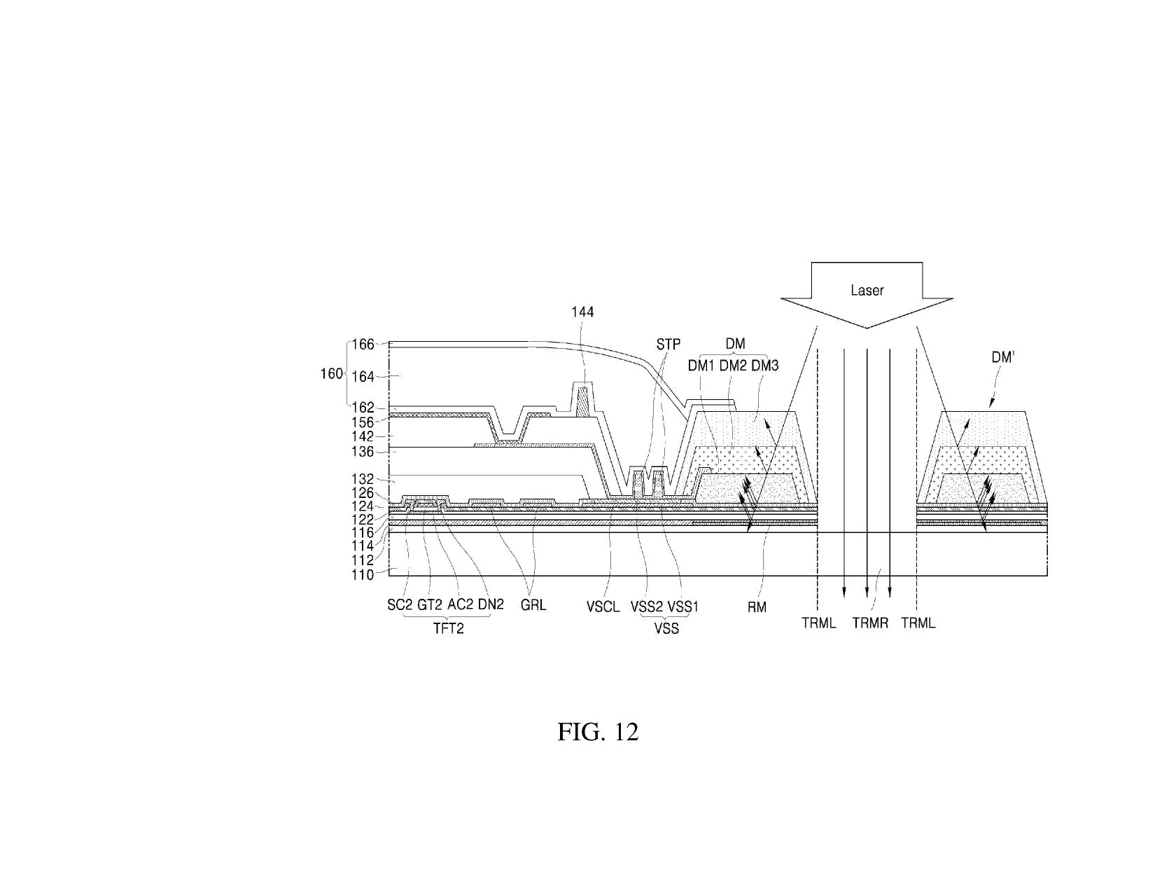

Referring to FIG. 12, the first buffer layer 112, the reflective layer RM, the second buffer layer 114, the third buffer layer 116, the gate insulating layer 122, the interlayer insulating layer 124, and the passivation layer 126 that are stacked on the edge of the non-display area NAA of the substrate 110 may include the opening that exposes the trimming area TRMR of the substrate 110. Both side surfaces of the opening passing through the first buffer layer 112, the reflective layer RM, the second buffer layer 114, the third buffer layer 116, the gate insulating layer 122, the interlayer insulating layer 124, and the passivation layer 126 may provide two trimming lines TRML.

The dam structure DM and the sacrificial dam structure DM’ may be disposed at both sides of the trimming area TRMR of the substrate 110. The dam structure DM and the sacrificial dam structure DM’ may be disposed on the passivation layer 126 while exposing the trimming area TRMR of the substrate 110. The sacrificial dam structure DM’ may have the same stacked structure as the dam structure DM. The lower end portion of the outer side surface of the dam structure DM may be aligned (for example, coincident) with one sidewall of the opening of the passivation layer 126. The lower end portion of the inner side surface of the sacrificial dam structure DM’ may be aligned (for example, coincident) with the other sidewall of the opening of the passivation layer 126.

Although the laser may be radiated to the wider area than the trimming area TRMR of the substrate 110, the laser radiated to areas other than the trimming area TRMR of the substrate 110 may be reflected at the plurality of interfaces within the dam structure DM and the sacrificial dam structure DM’. In addition, the laser that has transmitted the dam structure DM and the sacrificial dam structure DM’ may be reflected at the plurality of interfaces formed by the first buffer layer 112, the reflective layer RM, the second buffer layer 114, the third buffer layer 116, the gate insulating layer 122, the interlayer insulating layer 124, and the passivation layer 126. Accordingly, the trimming area TRMR of the substrate 110 may be accurately or relatively accurately removed, and areas of the substrate 110 other than the trimming area TRMR of the substrate 110 may not be removed by the laser trimming process.

Even when the laser is misaligned and radiated to the edge area of the substrate 110 due to various factors of laser trimming equipment, as described above, since the laser radiated to the areas other than the trimming area TRMR of the substrate 110 may be reflected by the stacked structure around the trimming area TRMR of the substrate 110, only the trimming area TRMR of the substrate 110 can be accurately or relatively accurately removed.

Accordingly, since there is no need to provide a laser trimming tolerance area on the edge of the substrate 110 in consideration of the misalignment of the laser trimming process, the width of the non-display area NAA of the display panel 100, that is, the bezel area, may be formed narrowly.

A display device according to various embodiments of the present disclosure may be described as follows.

According to embodiments of the present disclosure, there is provided a display device including a substrate including an display area and a non-display area surrounding the display area, a plurality of inorganic insulating layers which are disposed in the non-display area of the substrate and provide a plurality of interfaces at which a difference in refractive index occurs, and a dam structure including a plurality of organic insulating layers which are disposed on the plurality of inorganic insulating layers with a predetermined width on an edge of the non-display area of the substrate and provide a plurality of interfaces at which a difference in refractive index occurs, in which end portions of the plurality of inorganic insulating layers may be aligned (for example, coincident) with an end portion of the substrate.

According to some embodiments of the present disclosure, inner and outer side surfaces of the dam structure may be sloped surfaces, and a lower end portion of the outer side surface of the dam structure may be aligned (for example, coincident) with the end portion of the substrate.

According to some embodiments of the present disclosure, the dam structure may include a first organic insulating layer disposed on the plurality of inorganic insulating layers, a second organic insulating layer covering an upper surface and side surfaces of the first organic insulating layer, and a third organic insulating layer covering an upper surface and side surfaces of the second organic insulating layer, in which a lower end portion of a side surface of the third organic insulating layer may be aligned (for example, coincident) with the end portion of the substrate.

According to some embodiments of the present disclosure, the display device may further include a sloped structure disposed on an edge of the non-display area of the substrate, in which a thickness of the sloped structure may increase toward the end portion of the substrate.

According to some embodiments of the present disclosure, an end portion of the sloped structure may be aligned (for example, coincident) with the end portion of the substrate.

According to some embodiments of the present disclosure, the plurality of inorganic insulating layers may extend over the sloped structure to provide a plurality of interfaces sloped with respect to an upper surface of the substrate, and the dam structure may be disposed on the sloped structure to provide a plurality of interfaces sloped with respect to the upper surface of the substrate.

According to some embodiments of the present disclosure, the display device may further include an optical structure disposed on the dam structure and including a concave curved portion.

According to some embodiments of the present disclosure, an edge of the concave curved portion of the optical structure may be positioned on the dam structure, and a depth of the concave curved portion may increase toward the end portion of the substrate.

According to some embodiments of the present disclosure, the display device may further include a reflective layer overlapping the dam structure and disposed between the plurality of inorganic insulating layers.

According to some embodiments of the present disclosure, the display device may further include a reflective layer overlapping the dam structure and the sloped structure and disposed between the plurality of inorganic insulating layers.

According to some embodiments of the present disclosure, the display device may further include a reflective layer overlapping the dam structure and the optical structure and disposed between the plurality of inorganic insulating layers.

According to embodiments of the present disclosure, there is provided a display device including a substrate, a plurality of inorganic insulating layers that are disposed on an edge of the substrate and provide a plurality of interfaces at which light is reflected, and a reflective structure that includes a plurality of organic insulating layers that are disposed on the plurality of inorganic insulating layers on the edge of the substrate with a predetermined width and provide a plurality of interfaces at which light is reflected, in which end portions of the plurality of inorganic insulating layers may be aligned (for example, coincident) with an end portion of the substrate, and a lower end portion of an outer side surface of the reflective structure may be aligned (for example, coincident) with the end portion of the substrate.

According to some embodiments of the present disclosure, the display device may further include a sloped structure disposed on an edge of the substrate, in which a thickness of the sloped structure may increase toward the end portion of the substrate.

According to some embodiments of the present disclosure, an end portion of the sloped structure may be aligned (for example, coincident) with the end portion of the substrate.

According to some embodiments of the present disclosure, a plurality of inorganic insulating layers may be disposed on the sloped structure to provide a plurality of interfaces sloped with respect to an upper surface of the substrate, and a reflective structure may be disposed on the sloped structure to provide a plurality of interfaces sloped with respect to the upper surface of the substrate.

According to some embodiments of the present disclosure, the display device may further include an optical structure disposed on the dam structure and including a concave curved portion.

According to some embodiments of the present disclosure, the display device may further include a reflective layer overlapping the reflective structure and disposed between the plurality of inorganic insulating layers.

According to some embodiments of the present disclosure, the display device may further include a reflective layer overlapping the reflective structure and the sloped structure and disposed between the plurality of inorganic insulating layers.

According to some embodiments of the present disclosure, the display device may further include a reflective layer overlapping the reflective structure and the optical structure and disposed between the plurality of inorganic insulating layers.

Although the embodiments of the present disclosure have been described in more detail with reference to the accompanying drawings, the present disclosure is not necessarily limited to these embodiments, and various modifications may be carried out without departing from the technical spirit of the present disclosure. Accordingly, the embodiments disclosed in the present disclosure are not intended to limit the technical spirit of the present disclosure, but are intended to describe the technical spirit of the present disclosure and the scope of the technical spirit of the present disclosure is not limited by these embodiments. Accordingly, it should be understood that the above-described embodiments are illustrative and not restrictive in all aspects.

What is claimed is:

1. A display device comprising:
a substrate comprising a display area and a non-display area surrounding the display area;
a plurality of inorganic insulating layers which are disposed on the non-display area of the substrate, wherein the plurality of inorganic insulating layers provides a plurality of interfaces at which a difference in refractive index occurs; and
a dam structure comprising a plurality of organic insulating layers which are disposed on the plurality of inorganic insulating layers with a predetermined width on an edge of the non-display area of the substrate, wherein the plurality of inorganic insulating layers provides a plurality of interfaces at which a difference in refractive index occurs,
wherein an end portion of each of the plurality of inorganic insulating layers is aligned with an end portion of the substrate.

2. The display device of claim 1, comprising an inner side surface and an outer side surface,
wherein the inner surface and the outer side surface of the dam structure are sloped, and
wherein a lower end portion of the outer side surface of the dam structure is aligned with the end portion of the substrate.

3. The display device of claim 1, wherein the plurality of organic insulating layers comprises:
a first organic insulating layer disposed on the plurality of inorganic insulating layers;
a second organic insulating layer covering an upper surface and a plurality of side surfaces of the first organic insulating layer; and
a third organic insulating layer covering an upper surface and a plurality of side surfaces of the second organic insulating layer,
wherein a lower end portion of each of the plurality of side surfaces of the third organic insulating layer is aligned with the end portion of the substrate.

4. The display device of claim 1, further comprising a sloped structure disposed on the edge of the non-display area of the substrate, wherein a thickness of the sloped structure increases toward the end portion of the substrate.

5. The display device of claim 4, wherein an end portion of the sloped structure is aligned with the end portion of the substrate.

6. The display device of claim 4, wherein the plurality of inorganic insulating layers extends over the sloped structure to provide a plurality of interfaces sloped with respect to an upper surface of the substrate, and wherein the dam structure is disposed on the sloped structure to provide a plurality of interfaces sloped with respect to the upper surface of the substrate.

7. The display device of claim 1, further comprising an optical structure disposed on the dam structure, wherein the optical structure comprises a concave curved portion.

8. The display device of claim 7, wherein an edge of the concave curved portion of the optical structure is positioned on the dam structure, and wherein a depth of the concave curved portion increases toward the end portion of the substrate.

9. The display device of claim 1, further comprising a reflective layer overlapping the dam structure, wherein the reflective layer is disposed between the plurality of inorganic insulating layers.

10. The display device of claim 4, further comprising a reflective layer overlapping the dam structure and the sloped structure, wherein the reflective layer is disposed between the plurality of inorganic insulating layers.

11. The display device of claim 7, further comprising a reflective layer overlapping the dam structure and the optical structure, wherein the reflective layer is disposed between the plurality of inorganic insulating layers.

12. The display device of claim 11, wherein an outer end portion of the reflective layer is aligned with the end portion of the substrate.

13. A display device comprising:
a substrate;
a plurality of inorganic insulating layers which are disposed on an edge of the substrate, wherein the plurality of inorganic insulating layers provides a plurality of interfaces at which light is reflected; and
a reflective structure disposed on the plurality of inorganic insulating layers on the edge of the substrate with a predetermined width,
wherein an end portion of each of the plurality of inorganic insulating layers is aligned with an end portion of the substrate.

14. The display device of claim 13, wherein the reflective structure comprises a plurality of organic insulating layers which are disposed on the plurality of inorganic insulating layers on the edge of the substrate, wherein the plurality of organic insulating layers provides a plurality of interfaces at which light is reflected, and
wherein a lower end portion of an outer side surface of the reflective structure is aligned with the end portion of the substrate.

15. The display device of claim 14, further comprising a sloped structure disposed on the edge of the substrate, wherein a thickness of the sloped structure increases toward the end portion of the substrate.

16. The display device of claim 15, wherein a plurality of inorganic insulating layers are disposed on the sloped structure to provide a plurality of interfaces sloped with respect to an upper surface of the substrate, and
wherein a reflective structure is disposed on the sloped structure to provide a plurality of interfaces sloped with respect to the upper surface of the substrate.

17. The display device of claim 14, further comprising an optical structure disposed on the reflective structure, wherein the optical structure comprises a concave curved portion.

18. The display device of claim 14, further comprising a reflective layer overlapping the reflective structure, wherein the reflective layer is disposed between the plurality of inorganic insulating layers.

19. The display device of claim 15, further comprising a reflective layer overlapping the reflective structure and the sloped structure, wherein the reflective layer is disposed between the plurality of inorganic insulating layers.

20. The display device of claim 17, further comprising a reflective layer overlapping the reflective structure and the optical structure, wherein the reflective layer is disposed between the plurality of inorganic insulating layers.
